(19) United States
(12) Patent Application Publication
(10) Pub. No.: US 2012/0049156 A1
(43) Pub. Date: Mar. 1, 2012

(54) NITRIDE SEMICONDUCTOR DEVICE AND SEMICONDUCTOR OPTICAL DEVICE

(75) Inventors: Masataka OHTA, Osaka-shi (JP); Takeshi KAMIKAWA, Osaka-shi (JP)

(73) Assignee: SHARP KABUSHIKI KAISHA, Osaka-Shi (JP)

(21) Appl. No.: 13/211,966

(22) Filed: Aug. 17, 2011

(30) Foreign Application Priority Data
Aug. 26, 2010 (JP) 2010-190136

(51) Int. Cl. H01L 33/06

(52) U.S. Cl. 257/13; 257/E33.027; 257/E33.005

(57) ABSTRACT

A nitride semiconductor device which improves the light emission efficiency is provided. The nitride semiconductor light emitting device includes the nitride semiconductor layer having a growth surface and the nitride semiconductor layer (layered structure) which is formed on the growth surface of the semiconductor layer, and includes an active layer that has a quantum well structure. The active layer includes a quantum well layer including the nitride semiconductor containing Al. Further, the growth surface of the semiconductor layer includes a plane having an off angle at least in an a axis direction with respect to an m-plane, and the off angle in the a axis direction is larger than an off angle in a c axis direction.

This application is based on Japanese Patent Application No. 2010-190136 filed on Aug. 26, 2010, and the content of which is hereby incorporated by reference.

### BACKGROUND OF THE INVENTION

1. Field of the Invention

The present invention relates to a nitride semiconductor device and a semiconductor optical device having the nitride semiconductor device mounted thereon.

2. Description of Related Art

Nitride semiconductors represented by GaN, AlN, InN, and mixed crystals thereof have characteristics that band gaps Eg thereof are larger than those of AlGaInAs semiconductors or AlGaInP semiconductors and that they are semiconductor materials of the direct transition type. Therefore, these nitride semiconductors receive attention as materials of semiconductor light emitting devices including a semiconductor laser device which can emit light in a wavelength range from ultraviolet to green and a light emitting diode device which can cover a wide light emission wavelength range from ultraviolet to red, and a wide range of application thereof is thought of including a projector, a full color display, and further, environmental and medical fields.

Further, in recent years, research and development are vigorously conducted by research institutes with regard to, among semiconductor light emitting devices using the nitride semiconductor, semiconductor light emitting devices which emit light in the ultraviolet region, application of which is expected in very wide range of fields such as sterilization/water purification, various kinds of medical fields, and high speed degrading treatment of pollutants by emitting short-wavelength light.

In the semiconductor light emitting device using the nitride semiconductor, generally, as a substrate, a sapphire substrate is used. Further, as a growth surface of the substrate, a c-plane ((0001) plane) which is a polar plane is used. By laminating on the c-plane the nitride semiconductor layer including an active layer, the nitride semiconductor light emitting device is formed.

However, in the above mentioned semiconductor light emitting device, until now, there is an inconvenience that to improve the quality of AlN, AlGaN, and AlInGaN crystals is difficult. Therefore, there is a problem that to improve light emission efficiency of the light emitting device is difficult. As one reason for this, insufficient surface migration of Al atoms is suggested. As a measure to address this, a contrivance of a method of supplying raw material, effectiveness of high temperature growth and the like are proposed.

It should be noted that the above mentioned contrivance of the method of supplying the raw material is proposed in M. Hiroki and N. Kobayashi, “Flat Surfaces and Interfaces in AlN/GaN Heterostructures and Superlattices Grown by Flow-Rate Modulation Epitaxy”, Jpn. J. Appl. Phys. 42 (2003) 2305 (hereinafter referred to as Non Patent Literature 1). Further, the above mentioned effectiveness of high temperature growth is proposed in M. Imura, K. Nakano, N. Fujimoto, N. Okada, K. Balakrishnan, M. Iwaya, S. Kamiyama, H. Amano, I. Akasaki, T. Noro, T. Takagi, and A. Bando, “Dislocations in AlN Epilayers Grown on Sapphire Substrate by High-Temperature Metal-Organic Vapor Phase Epitaxy”, Jpn. J. Appl. Phys. 46 (2007) 1458 (hereinafter referred to as Non Patent Literature 2).

More specifically, in the above mentioned Non Patent Literature 1, when an AlN layer and an AlGaN layer which has high Al composition ratio are formed, a method is used in which a raw material of group III atoms and a raw material of group V atoms are not supplied at the same time but are supplied alternately. Further, the above mentioned Non Patent Literature 2 discloses that, when an AlN layer is grown on the c-plane of the sapphire substrate, by growth at a temperature as high as 1,400° C., the crystal quality of the AlN layer is improved.

Further, when the substrate having the c-plane that is the polar plane as the principal plane is used, as there is a polarity in a direction of a normal to the principal plane (in a direction of a c axis), and when the nitride semiconductor layer including an active layer is laminated on the c-plane, spontaneous polarization occurs in the active layer. Therefore, when the substrate having the c-plane as the principal plane is used, there is also a problem that, due to the spontaneous polarization, the light emission efficiency is reduced. Therefore, the nitride semiconductor laser device is also proposed in which, instead of the substrate having the principal plane which is the c-plane, the substrate having an m-plane which is a non polar plane as the principal plane is used. Such the nitride semiconductor laser device is proposed in, for example, Japanese Patent Application Laid-open No. 2009-158955 (hereinafter referred to as Patent Literature 1) and Japanese Patent Application Laid-open No. 2009-123969 (hereinafter referred to as Patent Literature 2).

However, even when the methods proposed in Non Patent Literatures 1 and 2 are used, the light emission efficiency is not sufficiently high, and there is still need to improve the light emission efficiency. Further, crystal growth at a high temperature as proposed in Non Patent Literature 2 has a problem that a temperature load on a growth furnace is heavy.

Further, even in Patent Literatures 1 and 2, the light emission efficiency is not sufficiently high, and further improvement in the light emission efficiency is required.

### SUMMARY OF THE INVENTION

The present invention has been made to solve the above mentioned problems, and an object of the present invention is to provide the nitride semiconductor device which can improve the light emission efficiency, and a semiconductor optical device including the nitride semiconductor device.

Another object of the present invention is to provide the nitride semiconductor device in which the nitride semiconductor layer is formed that has a satisfactory flatness, and the semiconductor optical device including the nitride semiconductor device.

The present inventors focused on the above mentioned problems, carried out various kinds of experiments and made a diligent study. As a result, it was found that, by forming the nitride semiconductor layer on a semiconductor layer that has a plane having an off angle with respect to the m-plane as the growth surface, the crystal quality can be improved.

Specifically, the nitride semiconductor device according to a first aspect of the present invention includes: a semiconductor layer including the nitride semiconductor, the semiconductor layer having a growth surface, and the nitride semiconductor layer formed on the growth surface of the semiconductor layer, the nitride semiconductor layer including an active layer which has a quantum well structure. The active layer includes a quantum well layer including the nitride semiconductor containing Al. Further, the growth surface of the semiconductor layer is formed of a plane having an off angle at least in an a axis direction with respect to an m-plane. The off angle in the a axis direction is configured to be larger than an off angle in a c axis direction.

In the nitride semiconductor device according to the first aspect, the plane having an off angle at least in the a axis direction with respect to the m-plane is the growth surface of the semiconductor layer as described above, and hence the crystal quality of the nitride semiconductor layer formed on the growth surface can be improved. Therefore, the crystal quality of the quantum well layer included in the nitride semiconductor layer can also be improved. This can improve the light emission efficiency.

Further, according to the first aspect, by setting the off angle in the a axis direction in the growth surface to be larger than the off angle in the c axis direction, the flatness of the nitride semiconductor layer formed on the growth surface can be improved. Therefore, this can also improve the light emission efficiency. Further, by improving the flatness of the nitride semiconductor layer, the in-plane layer thickness distribution can be uniformized, and thus, a generation of the crack, variations in device resistance, nonuniformity in current injection, and the like arising from nonuniformity in the in-plane layer thickness distribution can be suppressed.

Further, according to the first aspect, with the structure described above, the crystal quality and flatness of the nitride semiconductor layer can be improved without high temperature growth of the nitride semiconductor layer. Therefore, temperature load on the growth furnace can be reduced.

At this point, according to the first aspect, the growth surface of the semiconductor layer is formed of the plane having an off angle at least in the a axis direction with respect to the m-plane, and hence, as opposed to the case where the c-plane is the growth surface, spontaneous polarization which occurs in the active layer can be suppressed. Therefore, a reduction in the light emission efficiency arising from spontaneous polarization can also be suppressed.

In the nitride semiconductor device according to the above mentioned first aspect, it is preferable that both of the off angle in the a axis direction and the off angle in the c axis direction be larger than 0.1 degrees. With this structure, the crystal quality of the nitride semiconductor layer can be improved with ease, and the flatness of the nitride semiconductor layer can be improved with ease.

In the nitride semiconductor device according to the above mentioned first aspect, it is more preferred that the off angle in the a axis direction be larger than 0.1 degrees and equal to or smaller than 10 degrees. By setting the off angle in the a axis direction in this range, the effect of improving the crystal quality and the effect of improving the flatness can be obtained effectively.

In the nitride semiconductor device according to the above mentioned first aspect, it is further preferred that the off angle in the a axis direction be larger than one degree and equal to or smaller than 10 degrees. By setting the off angle in the a axis direction to be larger than one degree in this way, the effect of improving the crystal quality and the effect of improving the flatness can be obtained more effectively.

In the nitride semiconductor device according to the above mentioned first aspect, it is preferable that the above mentioned quantum well layer include a semiconductor represented by a composition formula of Alₓ₁In_{y1}Ga_{1-x1-y1}N (0<x1≦1 and 0≦y1≦1).

In this case, it is preferable that an Al composition ratio x1 in the quantum well layer be in a range of 0.15≦x1≦0.90. By setting the Al composition ratio x1 in the quantum well layer in this range, the light emission efficiency can be improved more effectively. At this point, the Al composition ratio x1 in the quantum well layer is more preferably equal to or larger than 0.3 and is further preferably equal to or larger than 0.5. By setting the Al composition ratio x1 in the quantum well layer to be equal to or larger than 0.15, when the growth surface used has an off angle at least in the a axis direction with respect to the m-plane, with the off angle in the a axis direction being larger than the off angle in the c axis direction, compared with a case where a plane other than the above mentioned plane (for example, the c-plane) is used, the effect of improving the light emission efficiency when compared with other planes (for example, the c-plane) can be increased. Further, by setting the Al composition ratio x1 in the quantum well layer to be equal to or larger than 0.3, the effect of improving the light emission efficiency when compared with other planes (for example, the c-plane) can be further increased, and, by setting the Al composition ratio x1 in the quantum well layer to be equal to or larger than 0.5, the effect of improving the light emission efficiency when compared with other planes (for example, c-plane) can be still further increased. Further, by setting the Al composition ratio x1 in the quantum well layer to be equal to or smaller than 0.9, carriers can be confined.

Further, it is preferable that, when the above mentioned quantum well layer includes the semiconductor represented by the composition formula of Alₓ₁In_{y1}Ga_{1-x1-y1}N, an In composition ratio y1 in the quantum well layer be in a range of 0.00≦y1≦0.12. More specifically, the above mentioned quantum well layer can be formed to contain In, or can be formed not to contain In. When the quantum well layer contains In, a quantum well layer which is excellent in flatness can be grown at a relatively low temperature. Therefore, the temperature load on the growth furnace (crystal growth system) can be effectively reduced. In addition, parameters for controlling distortion increase when the device structure is formed, and thus, the design flexibility of the device can be enhanced. Further, by setting the In composition ratio y1 to be equal to or smaller than 0.12, a crystal which is excellent in flatness can be materialized with ease. On the other hand, when the quantum well layer does not contain In, by forming the quantum well layer on the semiconductor layer having as the growth surface a plane having an off angle in the a axis direction, outstanding effect of improving the crystal quality and outstanding effect of improving the flatness can be obtained.

In the nitride semiconductor device according to the above mentioned first aspect, it is preferable that the semiconductor layer having the growth surface include the nitride semiconductor containing Al. In this case, it is preferable that an Al composition ratio in the semiconductor layer be larger than an Al composition ratio in the quantum well layer and be equal to or larger than 0.20 and equal to or smaller than 1.00. With this structure, the crystal quality of the nitride semiconductor layer can be improved and absorption by the semiconductor layer of light from the active layer can be suppressed. At this point, the Al composition ratio in the above mentioned semiconductor layer is more preferably equal to or larger than 0.3 and is further preferably equal to or larger than 0.5.

In the nitride semiconductor device according to the above mentioned first aspect, it is preferable that the active layer include a barrier layer which includes a semiconductor represented by a composition formula of Alₓ₂In_{y2}Ga_{1-x2-y2}N (0<x2≦1 and 0≦y2≦1), and that an Al composition ratio x2 in the barrier layer be larger than an Al composition ratio in the quantum well layer. With this structure, the band gap of the barrier layer becomes larger than the band gap of the quantum well layer.

In this case, it is preferable that the Al composition ratio x2 in the barrier layer be in a range of 0.20≦x2≦1.00. With this structure, the band gap of the barrier layer becomes larger than the band gap of the quantum well layer, and thus, carriers can be effectively confined in the quantum well, and absorption of light emitted in the active layer can be suppressed. At this point, the Al composition ratio x2 in the barrier layer is more preferably equal to or larger than 0.3 and is further preferably equal to or larger than 0.5.

Further, it is preferable that, when the above mentioned barrier layer includes the semiconductor represented by the composition formula of Alₓ₂In_{y2}Ga_{1-x2-y2}N and the above mentioned quantum well layer includes a semiconductor represented by a composition formula of Alₓ₁In_{y1}Ga_{1-x1-y1}N (0<x1≦1 and 0≦y1≦1), an In composition ratio y2 in the barrier layer be smaller than an In composition ratio y1 in the quantum well layer and be in a range of 0.00≦y2≦0.08. More specifically, the above mentioned barrier layer can be formed to contain In, or can be formed not to contain In. In either case, it is better that the band gap of the barrier layer is adapted to be larger than the band gap of the quantum well layer. When the barrier layer contains In, a barrier layer which is excellent in flatness can be grown at a relatively low temperature. Therefore, the temperature load on the growth furnace (crystal growth system) can be effectively reduced. In addition, parameters for controlling distortion increase when the device structure is formed, and thus, the design flexibility can be enhanced. Further, by setting the In composition ratio y1 to be equal to or smaller than 0.08, a crystal which is excellent in flatness can be materialized with ease. Further, by setting the In composition ratio y2 in the barrier layer to be smaller than the In composition ratio y1 in the quantum well layer, the band gap of the barrier layer is adapted to be larger than the band gap of the quantum well layer. Therefore, the influence of light absorption in the active layer can be suppressed. On the other hand, when the barrier layer does not contain In, by forming the quantum well layer on the semiconductor layer having as the growth surface a plane having an off angle in the a axis direction, outstanding effect of improving the crystal quality and outstanding effect of improving the flatness can be obtained.

In the structure in which the active layer includes the barrier layer, it is preferable that the barrier layer include AlGaN or AlInGaN.

Further, in the nitride semiconductor device according to the above mentioned first aspect, it is preferable that the quantum well layer include AlGaN or AlInGaN.

The nitride semiconductor device according to the above mentioned first aspect can further include an AlN layer formed on the growth surface of the semiconductor layer so as to be in contact with the growth surface. By forming the AlN layer so as to be in contact with the growth surface of the semiconductor layer in this way, an AlN layer which is excellent in crystallinity and flatness can be formed. Therefore, by laminating the semiconductor layer on the AlN layer, the crystallinity and flatness of the semiconductor layer laminated on the AlN layer can be improved.

In the nitride semiconductor device according to the above mentioned first aspect, it is preferable that the nitride semiconductor layer formed on the growth surface of the semiconductor layer further include an n-side nitride semiconductor layer formed on the semiconductor layer side with respect to the active layer, and a p-side nitride semiconductor layer formed on a side opposite to the n-side nitride semiconductor layer with respect to the active layer, and that the n-side nitride semiconductor layer do not include a GaN layer. With this structure, satisfactory surface morphology can be obtained.

In the nitride semiconductor device according to the above mentioned first aspect, it is preferable that a wavelength of light emitted from the active layer be equal to or larger than 240 nm and equal to or smaller than 360 nm. With this structure, a light emitting device which emits light in the ultraviolet region and has high light emission efficiency can be obtained.

In this case, it is more preferred that the wavelength of light emitted from the active layer be equal to or larger than 260 nm and equal to or smaller than 300 nm.

In the nitride semiconductor device according to the above mentioned first aspect, it is preferable that the semiconductor layer having the growth surface include one of AlGaN, AlInGaN, and AlN.

Further, the nitride semiconductor device according to the above mentioned first can further include a substrate which forms the semiconductor layer having the growth surface. In this case, it is preferable that the substrate include one of an AlGaN substrate, an AlInGaN substrate, and an AlN substrate. With this structure, the crystal quality of the nitride semiconductor layer formed on the substrate can be improved, and at the same time, the flatness of the nitride semiconductor layer can be improved.

In the nitride semiconductor device according to the above mentioned first aspect, the substrate which forms the semiconductor layer having the growth surface can include a GaN substrate. By using the GaN substrate as the substrate in this way, as opposed to a sapphire substrate or the like, the substrate itself is conductive, and hence, the design flexibility of the device can be enhanced. Further, when the GaN substrate is used as the substrate, compared with a case where the sapphire substrate is used, the differences in thermal expansion coefficient and in lattice constant from the nitride semiconductor layer formed on the substrate can be made smaller.

The nitride semiconductor device according to the above mentioned first aspect can further include a template substrate in which the semiconductor layer is formed on a base substrate, and can be configured so that the nitride semiconductor layer including the active layer is formed on the template substrate.

According to a second aspect of the present invention, the semiconductor optical device has the nitride semiconductor device according to the first aspect mounted thereon.

As described above, according to the present invention, the nitride semiconductor device which can improve the light emission efficiency, and the semiconductor optical device including the nitride semiconductor device can be obtained easily.

Further, according to the present invention, the nitride semiconductor device having a satisfactorily flat nitride semiconductor layer formed thereon, and the semiconductor optical device including the nitride semiconductor device can be obtained easily.

### BRIEF DESCRIPTION OF THE DRAWINGS

FIG. 1 is a schematic diagram for describing a crystal structure of a nitride semiconductor (diagram illustrating a unit cell);

FIG. 2 is a schematic diagram for describing off angles of a growth surface of a nitride semiconductor layer;

FIG. 3 is a sectional view illustrating the nitride semiconductor light emitting device according to a first embodiment of the present invention;

FIG. 4 is a sectional view illustrating a template substrate to be used in the nitride semiconductor light emitting device according to the first embodiment of the present invention;

FIG. 5 is a sectional view illustrating a structure of an active layer of the nitride semiconductor light emitting device according to the first embodiment of the present invention;

FIG. 6 is a sectional view schematically illustrating a semiconductor optical device according to the first embodiment of the present invention;

FIG. 7 is a sectional view illustrating the nitride semiconductor light emitting device according to a second embodiment of the present invention;

FIG. 8 is a sectional view illustrating a layered structure of the nitride semiconductor light emitting device according to a third embodiment of the present invention;

FIG. 9 is a sectional view illustrating the nitride semiconductor light emitting device according to a fourth embodiment of the present invention.

FIG. 10 is a sectional view illustrating a template substrate to be used in the nitride semiconductor light emitting device according to the fourth embodiment of the present invention;

FIG. 11 is a sectional view illustrating the nitride semiconductor light emitting device according to a fifth embodiment of the present invention;

FIG. 12 is a sectional view illustrating the nitride semiconductor light emitting device according to a sixth embodiment of the present invention;

FIG. 13 is a sectional view illustrating the nitride semiconductor light emitting device according to a modified example of the sixth embodiment.

FIG. 14 is a sectional view illustrating the nitride semiconductor light emitting device according to Example 1;

FIG. 15 is a sectional view illustrating a structure of an active layer of the nitride semiconductor light emitting device according to Example 1;

FIG. 16 is a sectional view illustrating the nitride semiconductor light emitting device according to Example 2;

FIG. 17 is a sectional view illustrating a structure of an active layer of the nitride semiconductor light emitting device according to Example 2;

FIG. 18 is a sectional view of an evaluation structure which was used to confirm effect of improving the light emission efficiency of the nitride semiconductor light emitting device according to Example 2; and

FIG. 19 is a sectional view illustrating a semiconductor substrate according to a seventh embodiment of the present invention.

### DETAILED DESCRIPTION OF PREFERRED EMBODIMENTS

Before specific embodiments of the present invention are described, findings obtained by the present inventors as a result of various kinds of studies are described.

The present inventors found that, when a nitride semiconductor layer containing Al was grown on the nitride semiconductor layer having an m-plane as the growth surface, compared with a case where the nitride semiconductor layer containing Al was grown on the nitride semiconductor having a c-plane as the growth surface, the crystal quality was improved. This is supposed to be because migration of group III atoms which reached a surface of a crystal was more extended on the nitride semiconductor layer having the m-plane as the growth surface than on the nitride semiconductor layer having the c-plane as the growth surface.

Here, a tendency was found that as Al composition ratio in the nitride semiconductor layer which was grown on the growth surface became larger, when the growth surface used, which had an off angle at least in an a axis direction with respect to the m-plane, with the off angle in the a axis direction being larger than an off angle in a c axis direction, compared with a case where a plane other than the above mentioned plane (for example, the c-plane) was used, the effect of improving the crystal quality became greater. More specifically, when the Al composition ratio in the nitride semiconductor layer containing Al was equal to or larger than 15%, the effect of improving the crystal quality when compared with other planes (for example, the c-plane) was great, and when the Al composition ratio was equal to or larger than 30%, the effect became very outstanding. The reason why, as the Al composition ratio becomes larger, the effect of improving the crystal quality when compared with other planes (for example, the c-plane) becomes greater is supposed to be that the diffusion constant of Al is smaller than the diffusion constant of Ga, and thus, when the Al composition ratio is set to be larger, the influence of Al atoms becomes greater, and effect to extend the migration is exerted greatly.

However, when the nitride semiconductor layer containing Al is grown on the nitride semiconductor layer having the m-plane as the growth surface, there is an inconvenience that pyramid-like protruding portions are formed on the growth surface. The pyramid-like protruding portions tended to be more conspicuous as the Al composition ratio in the nitride semiconductor layer which was grown on the growth surface became larger. More specifically, when the Al composition ratio is larger than 15% (0.15), the pyramid-like protruding portions appear conspicuously, and flatness of the growth surface becomes worse. When the Al composition ratio is equal to or larger than 30% (0.30), the flatness of the growth surface becomes still worse.

Therefore, the pyramid-like protruding portions magnify the unevenness of the growth surface. When the unevenness of the growth surface becomes magnified, the variations in the layer thickness become greater, and thus, a generation of the crack can be induced. Further, the in-plane layer thickness distribution becomes worse, and thus, problems such as variations in device resistance in a layer direction and nonuniformity in current injection in the in-plane direction arise, which results in problems such as reduced light emission efficiency, increased device resistance, and the like.

In this way, it was found that, when the nitride semiconductor layer containing Al was grown on the nitride semiconductor layer having an m-plane as the growth surface, if the Al composition ratio was set to be larger, the crystal quality was improved, but the pyramid-like protruding portions were formed, and thus, a problem that the flatness becomes worse arose.

The present inventors diligently made a study and found that, by causing a plane having an off angle at least in the a axis direction with respect to the m-plane to be the growth surface, the above mentioned problem can be solved. More specifically, the present inventors found that, by growing the nitride semiconductor layer containing Al on the nitride semiconductor layer that has, as the growth surface, the plane having an off angle at least in the a axis direction with respect to the m-plane, the crystal quality can be improved without forming the pyramid-like protruding portions. In this case, by causing the off angle in the a axis direction to be larger than the off angle in the c axis direction, generation of the pyramid-like protruding portions can be effectively suppressed.

Further, the present inventors found that, when the growth surface of the nitride semiconductor layer is formed as described above, by setting the Al composition ratio in the nitride semiconductor layer formed on the growth surface to be larger, while the satisfactory flatness of the growth surface is maintained, the crystal quality can be improved. Therefore, the nitride semiconductor layer having such a growth surface is suitable for a nitride semiconductor light emitting device which emits light in the ultraviolet region and which requires the nitride semiconductor layer with a large Al composition ratio.

At this point, the reason why the effect of improving the crystal quality can be obtained is supposed to be that migration of Al is extended, similarly to the case described above. Further, one reason why the effect of improving the flatness is obtained is supposed to be that, the growth surface of the nitride semiconductor layer has the off angle at least in the a axis direction with respect to the m-plane, and thus, the direction of migration of group III atoms is changed.

With the structure described above, the crystal quality and the flatness can be improved, and thus, the light emission efficiency can be improved. In addition, it was found that generation of a crack can be suppressed and the device resistance can be reduced.

Further study by the present inventors found that, when the nitride semiconductor layer that has, as the growth surface, the plane having an off angle at least in the a axis direction with respect to the m-plane was used and a device structure was formed on the growth surface, the growth temperature of a p-type nitride semiconductor layer could be lowered.

More specifically, the present inventors grew the p-type nitride semiconductor layer at a temperature lower than 900° C. and made a comparison. When the nitride semiconductor layer that has, as the growth surface, the c-plane that was the polar plane (for example, the c-plane GaN substrate) was used, it was confirmed that there were many defects due to threading dislocation or the like on the surface of the p-type nitride semiconductor layer. In this case, it was also confirmed that the size of the defects generated on the surface became larger. When defects on the surface are observed, ordinarily, the observation is difficult without using a scanning electron microscope (SEM) or the like. However, when the GaN substrate having the c-plane as the growth surface is used, large defects occur which can be observed even with an optical microscope at a magnification of about ×200 to ×800. The reason for this is supposed to be that the growth temperature is low, and thus, migration of atoms is suppressed and the crystallinity becomes worse. Further, the nitride semiconductor is likely to exhibit n-type conduction and is less likely to exhibit p-type conduction. Therefore, when the nitride semiconductor layer is grown at a low temperature, the crystallinity becomes worse, and thus, p-type conduction is not exhibited. In particular, in the case of an AlGaN type nitride semiconductor layer or the like containing Al, compared with a case of the GaN type nitride semiconductor layer or the like which does not contain Al, a higher growth temperature is required. In addition, when the Al composition ratio is large, growth at a temperature as high as about 1,200° C. is required in order to improve the crystal quality.

On the other hand, when the nitride semiconductor layer that has, as the growth surface, a plane having an off angle at least in the a axis direction with respect to the m-plane (for example, an m-plane GaN substrate) was used, compared with the case where the nitride semiconductor layer having the c-plane as the growth surface was used, the observed crystal surface was more flat and satisfactory. Further, when electrical characteristics were measured, satisfactory p-type conduction was exhibited.

At this point, the reason for obtaining such an effect is supposed to be that migration of atoms was sufficiently secured even when the growth temperature was set at a low level.

In the following, specific embodiments of the present invention will be described in detail with reference to the attached drawings. At this point, in the embodiments described below, cases where the present invention is applied to the nitride semiconductor light emitting device (light emitting diode device) as an example of a nitride semiconductor device will be described. Further, in the embodiments described below, a “nitride semiconductor” means a semiconductor formed of AlₓGa_{y}In_{z}N (0≦x≦1; 0≦y≦1; 0≦z≦1; and x+y+z=1).

### First Embodiment

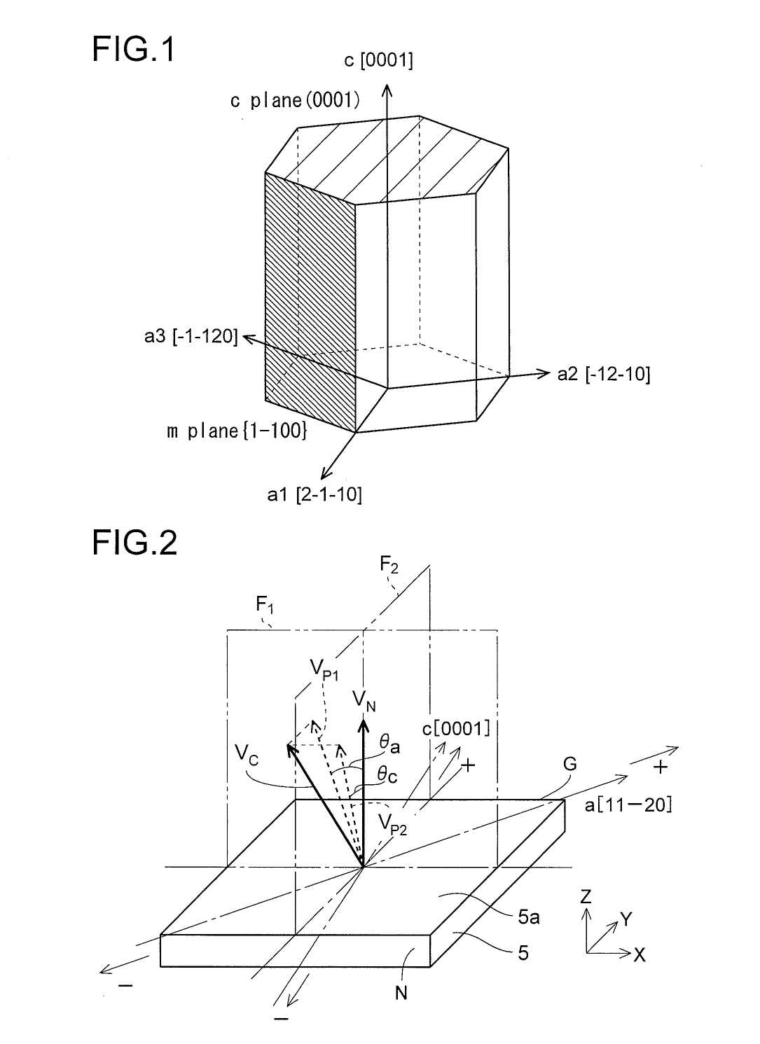

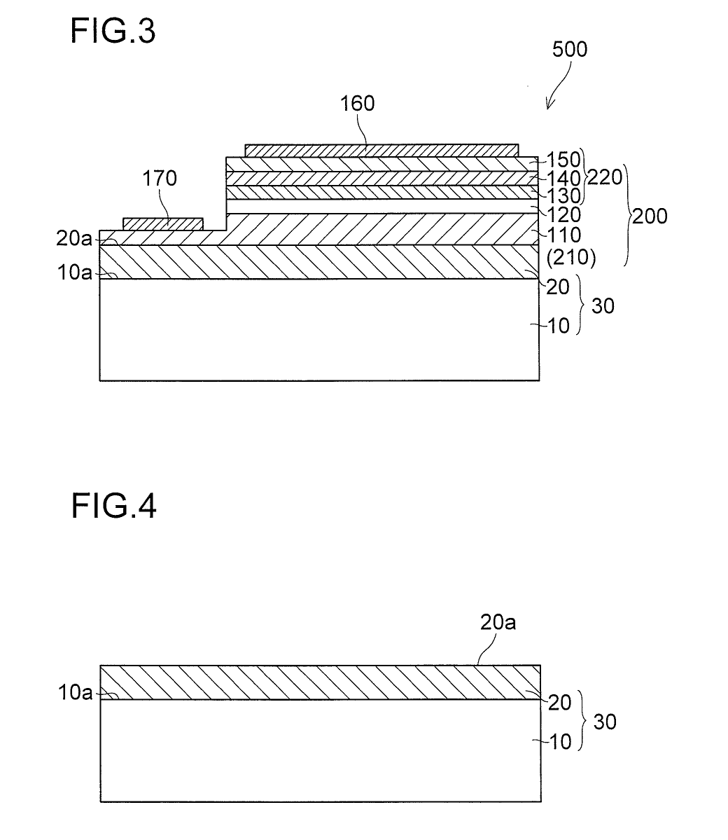

FIG. 1 is a schematic diagram for describing a crystal structure of the nitride semiconductor. FIG. 2 is a schematic diagram for describing off angles of a growth surface of the nitride semiconductor layer. FIG. 3 is a sectional view illustrating the nitride semiconductor light emitting device according to a first embodiment of the present invention. FIG. 4 to FIG. 6 are sectional views to explain the nitride semiconductor light emitting device according to the first embodiment of the present invention. First, a structure of the nitride semiconductor light emitting device 500 according to the first embodiment of the present invention will be described with reference to FIG. 1 to FIG. 6.

As illustrated in FIG. 1, the nitride semiconductor which forms the nitride semiconductor light emitting device 500 according to the first embodiment has a hexagonal crystal structure. In this crystal structure, a plane having a c axis [0001] of the hexagonal crystal that can be regarded as a hexagonal column (a top surface of the hexagonal column) as a normal to the plane is referred to as the c-plane (0001) while each of -side wall surfaces of the hexagonal column is referred to as an m-plane {1-100}. In the nitride semiconductor, no symmetry plane exists in the c axis direction, and thus, a polarization direction is the c axis direction. Therefore, the c-plane exhibits different properties on a +c axis -side and a −c axis -side. More specifically, the +c-plane ((0001) plane) and a −c-plane ((000-1) plane) are not equivalent planes and chemical properties thereof are also different. On the other hand, the m-plane is a crystal plane which is orthogonal to the c-plane, and thus, a normal to the m-plane is orthogonal to the polarization direction. It follows that the m-plane is a non polar plane without polarity. At this point, as described above, each of the -side wall surfaces of the hexagonal column is an m-plane, and thus, the m-planes are represented as six kinds of surface orientations ((1-100), (10-10), (01-10), (−1100), (−1010), and (0-110)). These surface orientations are equivalent to one another from a viewpoint of crystal geometry, and thus, these surface orientations are collectively represented as {1-100}.

Further, as illustrated in FIGS. 3 and 4, the nitride semiconductor light emitting device 500 according to the first embodiment has the nitride semiconductor layer 20 having the growth surface 20a. This growth surface 20a of the nitride semiconductor layer 20 is the plane having an off angle in the a axis direction ([11-20] direction) and having an off angle in the c axis direction (c axis: [0001] direction) with respect to the m-plane. Further, the off angle in the a axis direction in the growth surface 20a is set to be larger than the off angle in the c axis direction. At this point, the nitride semiconductor layer 20 is an example of a “semiconductor layer having a growth surface” according to the present invention.

Here, a GaN layer is taken as an example of the nitride semiconductor layer 20 having the growth surface 20a, and the off angle in the a axis direction and the off angle in the c axis direction are described in further detail with reference to FIG. 2. First, two crystal axis directions, i.e., the a axis [11-20] direction and the c axis [0001] direction with respect to the m-plane, are defined. The a axis and the c axis are orthogonal to each other, and are also orthogonal to an m axis. Further, it is assumed that, when a crystal axis vector (m axis: [1-100]) V_{C} of a GaN layer 5 is coincident with a normal vector V_{N} on a layer surface (growth surface 5a) (when the off angle is zero with respect to every direction), directions which are in parallel with the a axis direction, the c axis direction, and the m axis direction are an X direction, a Y direction, and a Z direction, respectively. Then, a first plane F₁ having a normal in the Y direction and a second plane F₂ having a normal in the X direction are considered. It is assumed that crystal axis vectors which appear when the crystal axis vector V_{C} is projected onto the first plane F₁ and the second plane F₂ are a first projection vector V_{P1} and a second projection vector V_{P2}, respectively. An angle θa formed here by the first projection vector V_{P1} and the normal vector V_{N} is the off angle in the a axis direction while an angle θc formed here by the second projection vector V_{P2} and the normal vector V_{N} is the off angle in the c axis direction. At this point, the off angle in the (+a) axis direction and the off angle in the (−a) axis direction result in the same surface state from a crystalline viewpoint, and thus, that in the (+a) direction and the (−a) direction have the same characteristics. Therefore, the indication can be provided by an absolute value. On the other hand, with regard to the c axis direction, there are two cases, in one of the (+c) direction and the (−c) direction, a Ga polar plane G becomes strong, and in the other, an N polar plane N becomes strong. The characteristics vary depending on the direction, and thus, the (+c) direction and the (−c) direction are distinguished from each other in the description.

Further, in the first embodiment, as illustrated in FIG. 4, the nitride semiconductor layer 20 is formed on the nitride semiconductor substrate 10 as a base substrate. A growth surface 10a of the nitride semiconductor substrate 10 is, similarly to the growth surface 20a of the nitride semiconductor layer 20, a plane having an off angle in the a axis direction and having an off angle in the c axis direction with respect to the m-plane. Further, the off angle in the a axis direction in the growth surface 10a is adapted to be larger than the off angle in the c axis direction. The nitride semiconductor layer 20 and the nitride semiconductor substrate 10 form so called a template substrate 30.

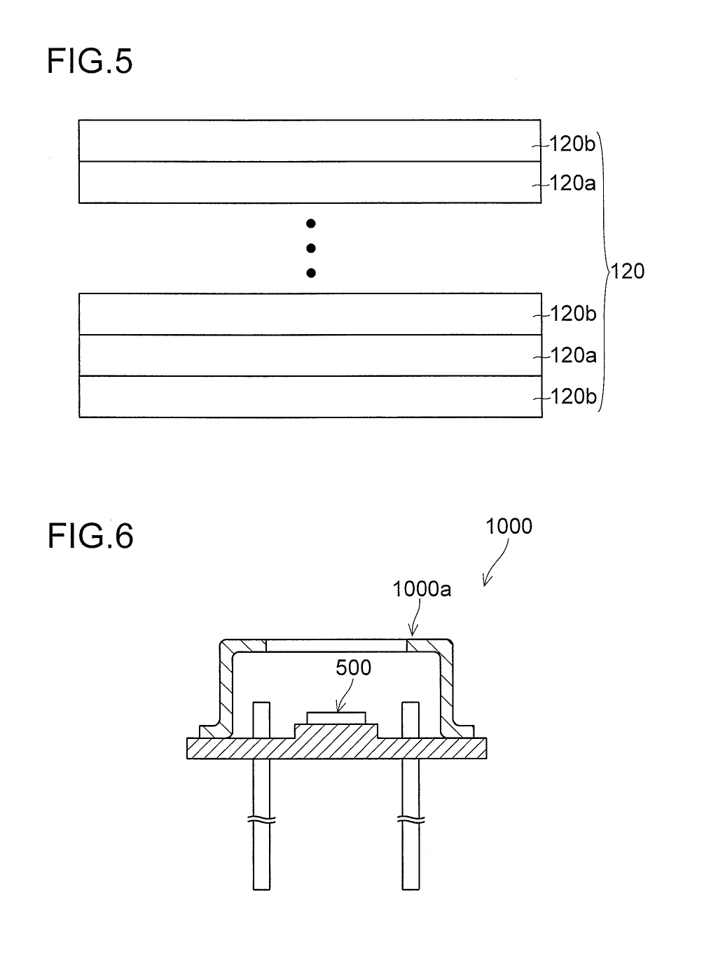

As the nitride semiconductor substrate 10, for example, a GaN substrate, an AlGaN substrate, an AlInGaN substrate, an AlN substrate, or the like can be used. Further, the nitride semiconductor layer 20 having the growth surface 20a is formed using the nitride semiconductor containing Al (for example, AlGaN, AlInGaN, or AlN). In this case, it is preferable that the Al composition ratio in the nitride semiconductor layer 20 be larger than the Al composition ratio in quantum well layers 120a (see FIG. 5) to be described below and be in a range of 0.20 or larger and 1.00 or smaller. Further, the Al composition ratio in the nitride semiconductor layer 20 is more preferably equal to or larger than 0.30 and is still more preferably equal to or larger than 0.50.

When a GaN substrate is used as the nitride semiconductor substrate 10, as opposed to a sapphire substrate or the like, a GaN substrate is conductive, and thus, the design flexibility of the device can be enhanced. Further, compared with a case where a heterosubstrate such as a sapphire substrate is used, the differences in thermal expansion coefficient and in lattice constant from an AlInGaN material are small, and thus, a GaN substrate is suitable for forming an AlInGaN layer. However, a GaN substrate absorbs ultraviolet light, and thus, design taking influence of light absorption into consideration is necessary.

When an AlGaN substrate is used as the nitride semiconductor substrate 10, by setting the Al composition ratio in the AlGaN substrate to be larger than the Al composition ratio in the quantum well layers 120a (see FIG. 5), the influence of light absorption is suppressed. Therefore, as opposed to the case where a GaN substrate is used, design taking the influence of light absorption into consideration becomes not necessary, and thus the design flexibility of the device structure can be enhanced. Further, by adjusting the Al composition ratio in the AlGaN substrate so that the lattice constant is similar to that of the AlInGaN material which forms the light emitting device, an effect of suppressing a crack can also be expected. In this case, it is better to cause the lattice constant to be similar to the lattice constant of, in a multilayer film (nitride semiconductor layers) forming the device structure, a layer having the largest thickness.

Further, when an AlGaN substrate is used as the nitride semiconductor substrate 10, the flexibility of the lattice constant of the substrate is enhanced, and thus, design flexibility of the nitride semiconductor forming the light emitting device is enhanced.

Further, when an AlN substrate is used as the nitride semiconductor substrate 10, in addition to the effect similar to the effect of the AlGaN substrate, heat dissipation is improved, and thus, light emission characteristics are expected to be improved.

Here, with regard to the growth surface 20a of the nitride semiconductor layer 20, both of the off angle in the a axis direction and the off angle in the c axis direction are set to be larger than 0.1 degrees. Further, the off angle in the a axis direction is more preferably larger than 0.1 degrees and equal to or smaller than 10 degrees, and is still more preferably larger than 1.0 degrees and equal to or smaller than 10 degrees. Further, with regard to the growth surface 10a of the nitride semiconductor substrate 10, also, it is preferable that the structure be similar to the above description.

A nitride semiconductor layer 200 (layered structure 200) including an active layer 120 is formed on the growth surface 20a of the nitride semiconductor layer 20. The nitride semiconductor layer 200 is formed by laminating a plurality of semiconductor layers, and includes an n-side nitride semiconductor layer 210 and a p-side nitride semiconductor layer 220. The n-side nitride semiconductor layer 210 and the p-side nitride semiconductor layer 220 are formed so as to sandwich the active layer 120 therebetween. Further, in the first embodiment, the n-side nitride semiconductor layer 210 is formed so as not to include a GaN layer.

More specifically, as illustrated in FIG. 3, on the growth surface 20a of the nitride semiconductor layer 20, for example, an n-type AlInGaN layer 110 having a thickness of about 1.5 μm to about 2.0 μm is formed. The above described active layer 120 is formed on the n-type AlInGaN layer 110. On the active layer 120, a carrier blocking layer 130 formed of p-type AlInGaN having a thickness of, for example, about 15 nm is formed. On the carrier blocking layer 130, a p-type AlInGaN layer 140 having a thickness of, for example, about 10 nm is formed. On the p-type AlInGaN layer 140, a p-type contact layer 150 formed of p-type AlInGaN having a thickness of, for example, about 50 nm is formed. At this point, the p-type contact layer 150 may also be formed of AlGaN or GaN.

As illustrated in FIG. 5, the active layer 120 has a quantum well structure in which barrier layers 120b and the quantum well layers 120a are alternately laminated. The quantum well layers 120a forming the active layer 120 are formed of semiconductor layers represented by a composition formula of Alₓ₁In_{y1}Ga_{1-x1-y1}N (0<x1≦1 and 0≦y1≦1). The barrier layers 120b are formed of semiconductor layers represented by a composition formula of Alₓ₂In_{y2}Ga_{1-x2-y2}N (0<x2≦1 and 0≦y2≦1). An Al composition ratio x2 in the barrier layers 120b is larger than an Al composition ratio x1 in the quantum well layers 120a.

The Al composition ratio x1 in the quantum well layers 120a is preferably in a range of 0.15≦x1≦0.90, more preferably in a range of 0.30≦x1≦1.00 according to other condition of the layers, and still more preferably in a range of 0.50≦x1≦1.00. Further, it is preferable that an In composition ratio y1 in the quantum well layers 120a be in a range of 0.00≦y1≦0.12.

The Al composition ratio x2 of the barrier layers 120b is preferably in a range of 0.20≦x2≦1.00, more preferably in a range of 0.30≦x2≦1.00, and still more preferably in a range of 0.50≦x2≦1.00. It is preferable that an In composition ratio y2 of the barrier layers 120b be in a range of 0.00≦y2≦0.08.

Further, the quantum well layers 120a may be formed of AlInGaN which contains In, or may be formed of AlGaN which does not contain In. Similarly, the barrier layers 120b may be formed of AlInGaN which contains In, or may be formed of AlGaN which does not contain In. When the barrier layers 120b contain In, it is preferable that the In composition ratio y2 therein be set to be smaller than the In composition ratio y1 in the quantum well layers 120a.

At this point, an Al composition ratio and an In composition ratio in the n-type AlInGaN layer 110 may be set to be the same as those in the barrier layers 120b. The composition ratios in the n-type AlInGaN layer 110 and in the barrier layers 120b may be different from each other, but when they set to be the same as described above, lattice mismatch at the interface is eliminated, which is preferable. When the composition of them are different, it is better that the band gap of the n-type AlInGaN layer 110 be set to be larger than the band gap of the barrier layers 120b. Such a structure enables effective confinement of carriers in the active layer 120.

An Al composition ratio and an In composition ratio in the p-type AlInGaN layer 140 may be, similarly to the case of the n-type AlInGaN layer 110, set to be the same as those in the barrier layers 120b. Alternatively, the composition ratios in the p-type AlInGaN layer 140 and in the barrier layers 120b may be different from each other.

Further, in the first embodiment, as illustrated in FIG. 3, the nitride semiconductor light emitting device 500 is structured in a so-called lateral structure light emitting diode device. Therefore, a part of the nitride semiconductor layer 200 (layered structure 200) formed on the template substrate 30 is dug in by dry etching or the like from the p-type contact layer 150 to midway through the n-type AlInGaN layer 110. An n-side electrode 170 is formed on a bottom surface of the dug portion (on the n-type AlInGaN layer 110). The n-side electrode 170 is, for example, an Al electrode or an Ag/Cu electrode having a multilayer structure in which an Ag layer and a Cu layer are laminated in this order from the substrate -side. On the other hand, a p-side electrode 160 is formed on the p-type contact layer 150. The p-side electrode 160 is, for example, an Ni/Au electrode having a multilayer structure in which an Ni layer (not shown) and an Au layer (not shown) are laminated in this order from the p-type contact layer 150 -side. In this way, in the first embodiment, the p-side electrode 160 and the n-side electrode 170 are formed on a top surface -side (growth surface 20a -side) of the template substrate 30 (nitride semiconductor layer 20). At this point, the metals used in the electrodes are only exemplary and the present invention is not limited thereto.

As described above, the nitride semiconductor light emitting device 500 according to the first embodiment is configured as a light emitting diode device which emits ultraviolet light (deep ultraviolet light) by forming the quantum well layers 120a utilizing the nitride semiconductor containing Al. At this point, the wavelength of light emitted from the active layer 120 is preferably equal to or larger than 240 nm and is equal to or smaller than 360 nm, more preferably equal to or larger than 250 nm and equal to or smaller than 320 nm, and still more preferably equal to or larger than 260 nm and equal to or smaller than 300 nm. When the wavelength of light emitted from the active layer 120 is equal to or larger than 240 nm, an energy gap at a heterointerface between the quantum well layer 120a and the barrier layer 120b or the like is large to some extent, and the effect of confining carriers becomes greater. Further, it is preferable that the wavelength of the light be equal to or smaller than 360 nm, because the active layer 120 is formed of AlInGaN. When the wavelength of the light is equal to or larger than 250 nm, the barrier of the carrier blocking layer 130 provided between the active layer 120 and the p-type contact layer 150 can be set to be relatively high with respect to the quantum well layers 120a, and hence, the effect of confining carriers becomes greater. When the wavelength of the light is equal to or smaller than 320 nm, the Al composition ratios in the quantum well layers 120a and in the barrier layers 120b become larger than about 30%, and thus, the effect of improving the crystal quality when compared with other planes (for example, the c-plane) becomes greater. When the wavelength of light emitted from the active layer 120 is in a range of 260 nm or larger and 300 nm or smaller, the effect of confining carriers and the like can be more effectively obtained.

The nitride semiconductor light emitting device 500 formed as described above is, as illustrated in FIG. 6, mounted on a can type package 1000a to form a semiconductor optical device 1000.

In the first embodiment, as described above, the growth surface 20a of the nitride semiconductor layer 20 is a plane having an off angle in the a axis direction and having an off angle in the c axis direction with respect to the m-plane, and further, the off angle in the a axis direction is set to be larger than the off angle in the c axis direction, which can improve the crystal quality of the nitride semiconductor layers 110 to 150 formed on the growth surface 20a. Therefore, the light emission efficiency of the nitride semiconductor light emitting device 500 can be improved. Further, the structure described above can effectively suppress the pyramid-like protruding portions which are observed when the nitride semiconductor layer containing Al is formed on the nitride semiconductor layer having the m-plane as the growth surface. Therefore, satisfactory surface morphology can be obtained, and the flatness of the nitride semiconductor layers 110 to 150 can be improved. This can cause the in-plane layer thickness distribution to be uniform, and thus, a generation of the crack, variations in device resistance, nonuniformity in current injection, and the like arising from nonuniformity in the in-plane layer thickness distribution can be suppressed.

At this point, by using the nitride semiconductor layer 20 having the growth surface 20a described above, the flatness and crystallinity of the nitride semiconductor layers 110 to 150 containing Al which are formed on the growth surface 20a can be improved, and hence, the flatness and crystallinity can be improved not only with respect to the active layer 120 but also with respect to the n-type AlInGaN layer 110, the carrier blocking layer 130, the p-type AlInGaN layer 140, and the p-type contact layer 150.

Further, it is preferable that the Al composition ratios in the n-type AlInGaN layer 110, the carrier blocking layer 130, the p-type AlInGaN layer 140, and the p-type contact layer 150 be equal to or larger than 0.20 and equal to or smaller than 1.00. It is preferable that the Al composition ratio in the carrier blocking layer 130 be larger than the Al composition ratio x2 in the barrier layers 120b and, at the same time, be in a range of 0.50 or larger and 1.00 or smaller. It is more preferred that the Al composition ratio in the carrier blocking layer 130 be in a range of 0.70 or larger and 1.00 or smaller. With this structure of the carrier blocking layer 130, carriers can be effectively confined in the active layer 120.

Further, in the first embodiment, with regard to the growth surface 20a of the nitride semiconductor layer 20, by setting the off angle in the a axis direction to be larger than 0.1 degrees, the crystal quality and flatness can be improved with ease. Further, by setting the off angle in the a axis direction to be larger than 1 degree, the crystal quality and flatness can be further improved. At this point, as the off angle in the a axis direction becomes larger, the amount of In which is taken in tends to be reduced, and hence, when the nitride semiconductor layer containing In (for example, an AlInGaN layer) is formed on the growth surface 20a, from the viewpoint of raw material efficiency and the like, it is preferable that the absolute value of the off angle in the a axis direction be, as described above, 10 degrees or smaller. By setting the off angle in the a axis direction in the growth surface 20a to be larger than 0.1 degrees and equal to or smaller than 10 degrees, the surface morphology of the nitride semiconductor layers 110 to 150 which are AlInGaN layers can become satisfactory. More specifically, the effect of improving the surface morphology can be obtained. Further, the operating voltage of the nitride semiconductor light emitting device 500 can be lowered.

Further, according to the study by the present inventors, when the nitride semiconductor layers containing Al are formed on the growth surface 20a of the nitride semiconductor layer 20 which has the above mentioned structure, and when the growth surface has an off angle at least in the a axis direction with respect to the m-plane, with the off angle in the a axis direction being larger than an off angle in the c axis direction, as the Al composition ratios in the nitride semiconductor layers containing Al become larger, the effect of improving the crystal quality when compared with other planes than the above mentioned plane (for example, the c-plane) becomes greater. Further, the effect of improving the flatness with respect to a plane having an off angle which is other than the one defined above with respect to the m-plane (for example, a plane which does not have an off angle in the a axis direction, and a plane having the off angle in the c axis direction that is larger than the off angle in the a axis direction) becomes greater. More specifically, the influence of the off angle becomes greater when the Al composition ratio is equal to or larger than 15% (0.15). With this structure, the effect of improving the surface and the effect of improving the light emission efficiency with respect to a plane having an off angle which is other than the one defined above with respect to the m-plane (for example, a plane which does not have an off angle in the a axis direction, and a plane having the off angle in the c axis direction larger than the off angle in the a axis direction) become greater. When the Al composition ratio is equal to or larger than 30% (0.30), not only the influence of the off angle but also the influence of migration becomes greater. Therefore, the effect of improving the crystal quality when compared with other planes (for example, the c-plane) becomes greater. Further, the effect of improving the surface with respect to a plane having an off angle which is other than the one defined above with respect to the m-plane (for example, a plane which does not have an off angle in the a axis direction, and a plane having the off angle in the c axis direction that is larger than the off angle in the a axis direction) becomes further greater, and the effect of improving the light emission efficiency becomes outstanding. Further, when the Al composition ratio is equal to or larger than 50% (0.50), the effect of improving the crystal quality when compared with other planes (for example, the c-plane) becomes greater. Further, the effect of improving the surface with respect to a plane having an off angle which is other than the one defined above with respect to the m-plane (for example, a plane which does not have an off angle in the a axis direction, and a plane having the off angle in the c axis direction that is larger than the off angle in the a axis direction) becomes further greater.

Therefore, setting the Al composition ratio x1 in the quantum well layers 120a to be equal to or larger than 0.15 (15%) can enhance the effect of improving the crystal quality and flatness of the quantum well layers 120a. Further, setting the Al composition ratio x1 in the quantum well layers 120a to be equal to or larger than 0.30 (30%) can further enhance the effect of improving the crystal quality and flatness of the quantum well layers 120a. Further, setting the Al composition ratio x1 to be equal to or larger than 0.50 (50%) can still further enhance the effect of improving the crystal quality and flatness of the quantum well layers 120a.

Further, by setting the Al composition ratio x1 in the quantum well layers 120a to be equal to or smaller than 0.90 (90%), an energy gap between the quantum well layer 120a and the barrier layer 120b and an energy gap between the quantum well layer 120a and the carrier blocking layer 130 can be secured to some extent, which enables carrier confinement.

Further, by setting the Al composition ratio x2 in the barrier layers 120b to be larger than the Al composition ratio x1 in the quantum well layers 120a, and at the same time, to be equal to or larger than 0.20 (20%) and equal to or smaller than 1.00 (100%), the band gap of the barrier layers 120b is set to be larger than the band gap of the quantum well layers 120a, and thus, carriers can be effectively confined in the quantum well. In addition, absorption of light from the active layer 120 can be suppressed. Further, by setting the Al composition ratio x2 in the barrier layers 120b to be equal to or larger than 0.30 (30%), the crystal quality and flatness of the barrier layers 120b can be further improved. By setting the Al composition ratio x1 to be equal to or larger than 0.50 (50%), the crystal quality and flatness of the barrier layers 120b can be still further improved.

At this point, the Al composition ratio x2 and the In composition ratio y2 in the barrier layers 120b are more preferably the same as those in a layer of the n-side nitride semiconductor layer 210 formed between the barrier layer 120b and the nitride semiconductor layer 20 which is adjacent to the barrier layer 120b. With this structure, lattice mismatch at the interface can be reduced.

Further, the layered structure 200 (nitride semiconductor layers, device structure) forming the nitride semiconductor light emitting device 500 can be formed by epitaxial growth (crystal growth) such as metal organic chemical vapor deposition (MOCVD) or molecular beam epitaxy (MBE).

Here, when an AlGaN layer or an AlN layer having a large Al composition ratio is formed, if MOCVD is used in order to extend migration of group III atoms to improve the crystal quality, the growth temperature is often set to be as high as 1,200° C. or higher. However, in a temperature range which exceeds 1,200° C., the temperature load on the crystal growth system (MOCVD system) becomes heavier.

On the other hand, in the first embodiment, with the above mentioned structure of the growth surface 20a of the nitride semiconductor layer 20, the crystal quality can be improved even in a conventionally used temperature range. Further, migration can be appropriately controlled even in a temperature range which is lower than the conventionally used temperature range, and thus, the temperature can be lowered. Therefore, the temperature load on the crystal growth system (MOCVD system) can be reduced. Further, growth in a temperature range in which vaporization of Ga can be suppressed is possible. In addition, even in the case of growth at a temperature lower than a conventionally used growth temperature (for example, about 1,000° C.), degradation in flatness can be suppressed.

Further, by forming the quantum well layer 120a by the nitride semiconductor layer containing In (for example, an AlInGaN layer), a layer which is excellent in flatness can be formed at a lower temperature. Therefore, taking into consideration the temperature load on the crystal growth system, it is preferable that the quantum well layer 120a be the nitride semiconductor layer containing Al and In (for example, an AlInGaN layer). Further, by forming the quantum well layer 120a of the nitride semiconductor layer containing Al and In (for example, an AlInGaN layer) in this way, parameters for controlling distortion increase by one, and hence, the design flexibility can be enhanced. Further, by setting the In composition ratio y to be equal to or smaller than 12% (0.12), a crystal which is excellent in flatness can be materialized.

On the other hand, the quantum well layer 120a can also be formed of the nitride semiconductor layer which does not contain In (for example, an AlGaN layer). With this structure, the effect of improving the crystal quality and the effect of improving the flatness can be further enhanced. More specifically, when the nitride semiconductor layer 20 having the growth surface 20a is used, by growing on the growth surface 20a the nitride semiconductor layer which does not contain In (for example, an AlGaN layer), an outstanding effect of improving the crystal quality and outstanding effect of improving the flatness can be obtained. Further, by forming the quantum well layer 120a of an AlGaN layer, the effect of lowering the operating voltage of the light emitting device can also be obtained, which is preferred. In addition, the amount of usage of In can be made smaller, which is preferred from the viewpoint of manufacturing costs.

Further, by forming the barrier layer 120b of the nitride semiconductor layer containing In (for example, an AlInGaN layer), similarly to the case of the quantum well layer 120a, a layer which is excellent in flatness can be formed at a lower temperature. Therefore, taking into consideration the temperature load on the crystal growth system, it is preferable that the barrier layer 120b be the nitride semiconductor layer containing Al and In (for example, an AlInGaN layer).

Further, by forming the barrier layer 120b of the nitride semiconductor layer containing Al and In (for example, an AlInGaN layer) in this way, parameters for controlling distortion increase by one, and hence, the design flexibility can be enhanced. At this point, by setting the In composition ratio y to be equal to or smaller than 8% (0.80), a crystal which is excellent in flatness can be materialized.

Further, the barrier layer 120b can also be formed of the nitride semiconductor layer which does not contain In (for example, an AlGaN layer). With this structure, similarly to the case of the quantum well layer 120a, the effect of improving the crystal quality and the effect of improving the flatness can be further enhanced. Further, by forming, together with the quantum well layer 120a, the barrier layer 120b of an AlGaN layer, the effect of lowering the operating voltage of the light emitting device can be effectively obtained, which is preferred.

Further, in the first embodiment, by forming the n-side nitride semiconductor layer 210 so as not to contain a GaN layer, degradation in flatness can be suppressed. More specifically, when a GaN layer intentionally doped with no impurities, or an n-type GaN layer doped with n-type impurities (for example, Si) is formed having a thickness of about 1.0 μm on the nitride semiconductor layer 20 having a plane having an off angle in the a axis direction and having an off angle in the c axis direction with respect to the m-plane as the growth surface 20a, with the off angle in the a axis direction being larger than the off angle in the c axis direction, a phenomenon in which the surface of the crystal is very rough is observed. On the other hand, in the case of a p-type GaN layer intentionally doped with p-type impurities (for example, Mg), a flat surface can be realized. This phenomenon is unique to the growth surface having the above mentioned structure. Therefore, by causing an n-type GaN layer or an i-type GaN layer not to be formed, roughness on the surface of the crystal can be suppressed, which can also improve the flatness. Further, a GaN layer absorbs light in the ultraviolet region, and hence, by causing a GaN layer not to be provided, absorption of light emitted from the active layer 120 can be suppressed.

At this point, when a GaN substrate is used as the nitride semiconductor substrate 10, a GaN substrate absorbs ultraviolet light, and hence, it is preferable that a general technology of peeling the substrate be used to peel (remove) the GaN substrate.

### Second Embodiment

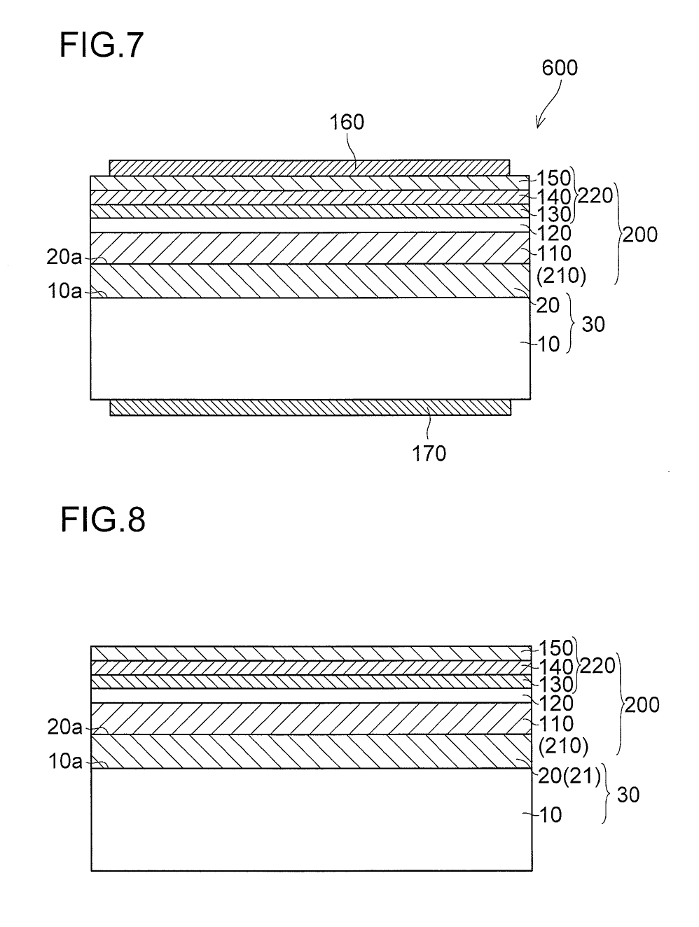

FIG. 7 is a sectional view illustrating the nitride semiconductor light emitting device according to a second embodiment of the present invention. Next, the nitride semiconductor light emitting device 600 according to the second embodiment of the present invention is described with reference to FIGS. 5 and 7. At this point, in FIG. 7, the same reference symbols are used to designate corresponding structural elements and redundant description thereof is omitted as appropriate.

The nitride semiconductor light emitting device 600 according to the second embodiment is, as illustrated in FIG. 7, a so-called vertical structure light emitting diode device. More specifically, the n-side electrode 170 is formed on a rear surface of the nitride semiconductor substrate 10 while the p-side electrode 160 is formed on the p-type contact layer 150.

In the case of a vertical structure, the template substrate 30 is a conductive substrate, and hence, it is preferable that, as the nitride semiconductor substrate 10 which forms the template substrate 30, a conductive substrate, for example, a GaN substrate, an AlGaN substrate, or an AlInGaN substrate be used.

When a GaN substrate is used as the nitride semiconductor substrate 10, as opposed to a sapphire substrate or the like, a GaN substrate is conductive, and thus, the design flexibility of the device can be enhanced. Further, compared with a case where a heterosubstrate such as a sapphire substrate is used, the differences in thermal expansion coefficient and in lattice constant from an AlInGaN material are small, and thus, a GaN substrate is suitable for forming an AlInGaN layer. However, a GaN substrate absorbs ultraviolet light, and thus, design taking light absorption into consideration is necessary.

When an AlGaN substrate is used as the nitride semiconductor substrate 10, by setting the Al composition ratio in the AlGaN substrate to be larger than the Al composition ratio in the quantum well layers 120a (see FIG. 5), the influence of light absorption is suppressed and, as opposed to the case where a GaN substrate is used, design taking light absorption into consideration is unnecessary. Therefore, the design flexibility of the device structure can be enhanced. Further, by adjusting the Al composition ratio in the AlGaN substrate so that the lattice constant is similar to that of the AlInGaN material which forms the light emitting device, an effect of suppressing a crack can also be expected. In this case, it is better to set the lattice constant to be similar to the lattice constant of, in a multilayer film (nitride semiconductor layers) forming the device structure, a layer having the largest thickness.

Further, when an AlGaN substrate is used as the nitride semiconductor substrate 10, the flexibility of the lattice constant of the substrate is enhanced, and thus, the design flexibility of the nitride semiconductor forming the light emitting device is enhanced.

At this point, when the nitride semiconductor substrate 10 exhibits conductivity, from the viewpoint of conductivity, it is better that the nitride semiconductor layer 20 formed on the growth surface 10a of the nitride semiconductor substrate 10 (nitride semiconductor layer 20 forming the template substrate 30) be formed of AlGaN or AlInGaN. AlGaN and AlInGaN exhibit relatively satisfactory conductivity compared with AlN, and thus, electrodes can be formed above and below the nitride semiconductor layer 200 (layered structure 200 (device structure)) to realize the vertical structure nitride semiconductor light emitting device 600.

Further, the layered structure 200 (nitride semiconductor layers 110 to 150 (nitride semiconductor layer 200)) formed on the template substrate 30 can be, similarly to the case of the first embodiment, formed of AlInGaN, or, as opposed to the case of the first embodiment, formed of AlGaN. Alternatively, the layered structure 200 can be formed of AlInGaN and AlGaN in a mixed manner. For example, when the active layer 120 is formed of an AlGaN layer, it is preferable that the n-side nitride semiconductor layer 210 and the p-side nitride semiconductor layer 220 which sandwich the active layer 120 therebetween also be formed of AlGaN layers.

At this point, it is also possible to use an AlN substrate as the nitride semiconductor substrate 10 and to form the nitride semiconductor layer 20 of an AlN layer. In that case, by peeling (removing) the AlN substrate and the AlN layer, a vertical structure nitride semiconductor light emitting device can be manufactured.

Other structures and effects of the second embodiment are similar to those of the first embodiment.

### Third Embodiment

FIG. 8 is a sectional view illustrating a layered structure of the nitride semiconductor light emitting device according to a third embodiment of the present invention. Next, the nitride semiconductor light emitting device according to the third embodiment of the present invention is described with reference to FIG. 8.

In the nitride semiconductor light emitting device according to the third embodiment, as illustrated in FIG. 8, the nitride semiconductor layer 20 which forms the template substrate 30 is formed of a GaN layer 21. Further, in the third embodiment, the GaN layer 21 (nitride semiconductor layer 20) is formed having a thickness of 0.7 μm or smaller. At this point, the thickness of the GaN layer 21 (nitride semiconductor layer 20) is more preferably equal to or smaller than 0.5 μm, and still more preferably equal to or smaller than 0.2 μm.

As described above, when a GaN layer intentionally doped with no impurities, or an n-type GaN layer doped with n-type impurities (for example, Si) is formed having a thickness of about 1.0 μm on the nitride semiconductor layer (nitride semiconductor substrate) that has, as the growth surface, a plane having an off angle in the a axis direction and having an off angle in the c axis direction with respect to the m-plane, with the off angle in the a axis direction being larger than the off angle in the c axis direction, a phenomenon that the surface of the crystal is very rough is observed. On the other hand, in the case of a p-type GaN layer intentionally doped with p-type impurities (for example, Mg), a flat surface can be realized. This phenomenon is unique to the growth surface having the above mentioned structure. Therefore, when a GaN layer having a thickness of about 1.0 μm is formed as the nitride semiconductor layer 20 on the growth surface 10a of the nitride semiconductor substrate 10, the surface of the crystal can become rough.

On the other hand, even when a GaN layer is formed as the nitride semiconductor layer 20 on the growth surface 10a of the nitride semiconductor substrate 10, by making smaller the thickness thereof, the extent of the influence of the off angle (rough surface) can be made smaller. In this case, by setting the thickness of the GaN layer 21 (nitride semiconductor layer 20) to be equal to or smaller than 0.5 μm, the influence thereof can become further smaller. By setting the thickness of the GaN layer 21 (nitride semiconductor layer 20) to be equal to or smaller than 0.2 μm, the influence thereof can become still smaller.

At this point, the device structure (nitride semiconductor layers 110 to 150 (nitride semiconductor layer 200)) formed on the growth surface 20a of the template substrate 30 is similar to those in the first and second embodiments. Further, the nitride semiconductor light emitting device according to the third embodiment can be any one of a vertical structure nitride semiconductor light emitting device and a lateral structure nitride semiconductor light emitting device. Here, the n-side electrode and the p-side electrode can have structures similar to those of the electrodes described in the first and second embodiments.

Further, effects of the third embodiment are similar to those of the first and second embodiments.

### Fourth Embodiment

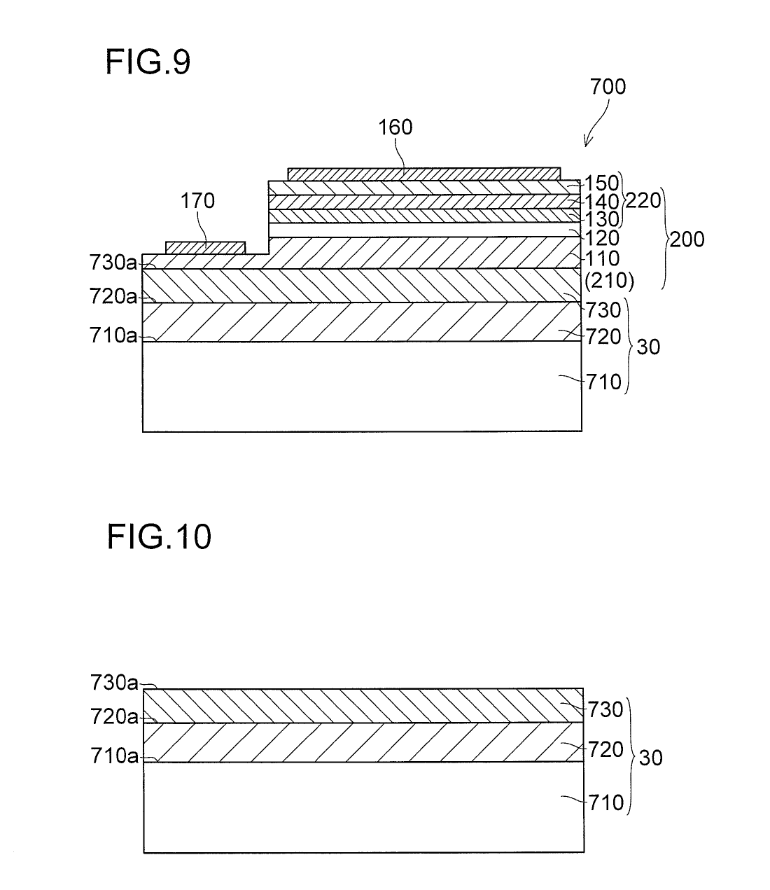

FIG. 9 is a sectional view illustrating the nitride semiconductor light emitting device according to a fourth embodiment of the present invention. FIG. 10 is a sectional view illustrating a template substrate to be used in the nitride semiconductor light emitting device according to the fourth embodiment of the present invention. Next, the nitride semiconductor light emitting device 700 according to the fourth embodiment of the present invention is described with reference to FIGS. 9 and 10. At this point, in FIGS. 9 and 10, the same reference symbols are used to designate corresponding structural elements and redundant description thereof is omitted as appropriate.

In the fourth embodiment, as illustrated in FIGS. 9 and 10, a base substrate 710 which forms the template substrate 30 is a substrate other than the nitride semiconductor substrate. More specifically, in the fourth embodiment, the base substrate 710 is, for example, a sapphire substrate, a SiC substrate, a Si substrate, or the like.

A first nitride semiconductor layer 720 is formed on a growth surface 710a of the base substrate 710. The first nitride semiconductor layer 720 is, for example, an AlN layer, an AlGaN layer, or an AlInGaN layer. It is more preferred that the first nitride semiconductor layer 720 be an AlN layer. Further, a growth surface 720a of the first nitride semiconductor layer 720 is, similarly to the case of the first to third embodiments, a plane having an off angle in the a axis direction and having an off angle in the c axis direction with respect to the m-plane, with the off angle in the a axis direction being larger than the off angle in the c axis direction. At this point, the off angle in the a axis direction is more preferably larger than 0.1 degrees and equal to or smaller than 10 degrees, and is further preferably larger than 1.0 degrees and equal to or smaller than 10 degrees.

Further, in the fourth embodiment, a second nitride semiconductor layer 730 is further formed on the growth surface 720a of the first nitride semiconductor layer 720. The second nitride semiconductor layer 730 is, for example, an AlN layer, an AlGaN layer, or an AlInGaN layer. At this point, the first nitride semiconductor layer 720 and the second nitride semiconductor layer 730 are examples of the “semiconductor layer having a growth surface” according to the present invention.

As the Al composition ratio in the nitride semiconductor layer (second nitride semiconductor layer 730) formed on the growth surface 720a which is a plane having an off angle in the a axis direction and having an off angle in the c axis direction with respect to the m-plane, with the off angle in the a axis direction being larger than the off angle in the c axis direction, becomes larger, the effect of improving the crystallinity and flatness when compared with other planes can become greater. Therefore, by causing the second nitride semiconductor layer 730 to be an AlN layer, the effect of improving the crystal quality and flatness become greater.

Further, a growth surface 730a of the second nitride semiconductor layer 730 formed on the growth surface 720a of the first nitride semiconductor layer 720 is also, similarly to the growth surface 720a, a plane having an off angle in the a axis direction and having an off angle in the c axis direction with respect to the m-plane, with the off angle in the a axis direction being larger than the off angle in the c axis direction.

Further, a device structure (nitride semiconductor layers 110 to 150 (nitride semiconductor layer 200)) similar to those in the first to third embodiments is formed on the growth surface 730a of the template substrate 30. At this point, the nitride semiconductor layers 110 to 150 can be formed of AlInGaN or can be formed of AlGaN.

In the fourth embodiment, as described above, by causing the growth surface 730a of the nitride semiconductor template 720, 730 formed on the base substrate 710 which is a sapphire substrate, a SiC substrate, a Si substrate, or the like to be a plane having an off angle in the a axis direction and having an off angle in the c axis direction with respect to the m-plane, with the off angle in the a axis direction being larger than the off angle in the c axis direction, the crystal quality and flatness of the nitride semiconductor layers 110 to 150 formed on the growth surface 730a can be improved. Therefore, when the nitride semiconductor light emitting device is manufactured, the light emission efficiency thereof can be improved.

At this point, the template substrate 30 in the fourth embodiment can have a structure without the second nitride semiconductor layer 730.

Further, when a sapphire substrate is used as the base substrate 710, as illustrated in FIG. 9, the nitride semiconductor light emitting device 700 can have a lateral structure. Further, when at least one of the first nitride semiconductor layer 720 and the second nitride semiconductor layer 730 is an AlN layer, which is inferior in conductivity to an AlGaN layer, an AlInGaN layer, or the like, it is better to cause the nitride semiconductor light emitting device 700 to have a lateral structure as illustrated in FIG. 9.

On the other hand, when the template substrate 30 is conductive, the nitride semiconductor light emitting device 700 can have a vertical structure.

Other structures and effects of the fourth embodiment are similar to those of the first and second embodiments.

### Fifth Embodiment

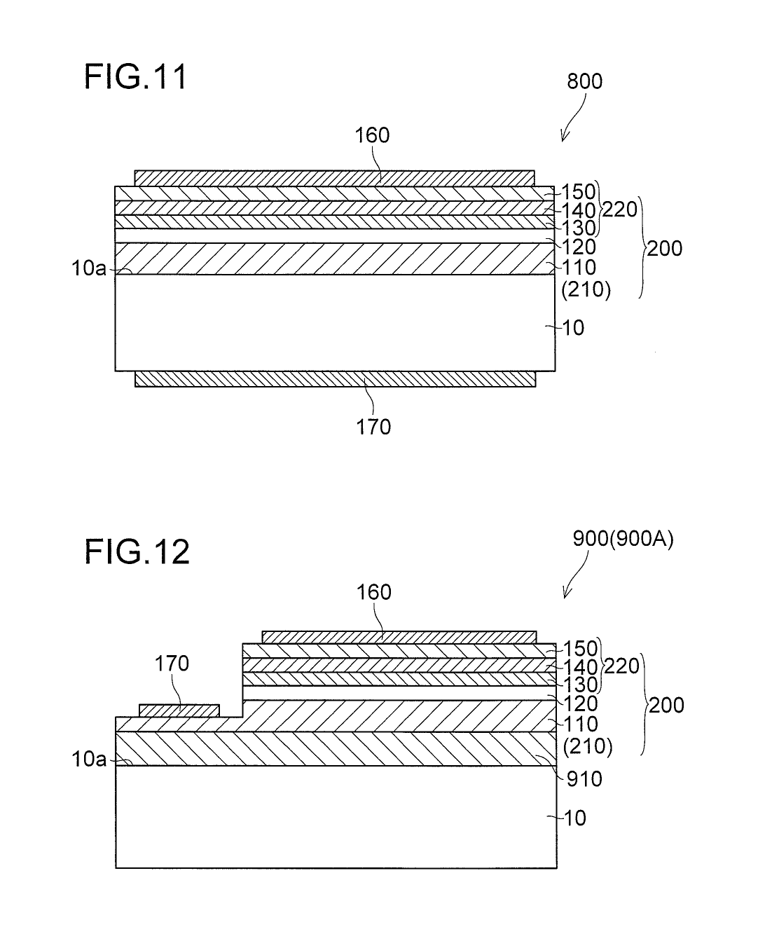

FIG. 11 is a sectional view illustrating the nitride semiconductor light emitting device according to a fifth embodiment of the present invention. Next, the nitride semiconductor light emitting device 800 according to the fifth embodiment of the present invention is described with reference to FIG. 11. At this point, in FIG. 11, the same reference symbols are used to designate corresponding structural elements and redundant description thereof is omitted as appropriate.

In the fifth embodiment, as illustrated in FIG. 11, the layered structure 200 (nitride semiconductor layers 110 to 150) is directly formed on the growth surface 10a of the nitride semiconductor substrate 10. The nitride semiconductor substrate 10 is, for example, a GaN substrate, an AlGaN substrate, an AlInGaN substrate, or an AlN substrate. The growth surface 10a of the nitride semiconductor substrate 10 is, similarly to the case of the first to fourth embodiments described above, a plane having an off angle in the a axis direction and having an off angle in the c axis direction with respect to the m-plane, with the off angle in the a axis direction being larger than the off angle in the c axis direction. The off angle in the a axis direction is more preferably larger than 0.1 degrees and equal to or smaller than 10 degrees, and is still more preferably larger than 1.0 degrees and equal to or smaller than 10 degrees. At this point, the nitride semiconductor substrate 10 in the fifth embodiment is an example of the “semiconductor layer having a growth surface” according to the present invention.

Further, a device structure (nitride semiconductor layers 110 to 150) similar to those in the above mentioned first to fourth embodiments is formed on the growth surface 10a of the nitride semiconductor substrate 10. At this point, when the nitride semiconductor substrate 10 is a conductive substrate, as illustrated in FIG. 11, the nitride semiconductor light emitting device 800 can have a vertical structure. Further, when the nitride semiconductor substrate 10 is an AlN substrate, which is inferior in conductivity to a GaN substrate, an AlGaN substrate, an AlInGaN substrate, or the like, it is better to cause the nitride semiconductor light emitting device to have a lateral structure.

In the fifth embodiment, as described above, by causing the growth surface 10a of the nitride semiconductor substrate 10 to be a plane having an off angle in the a axis direction and having an off angle in the c axis direction with respect to the m-plane, with the off angle in the a axis direction being larger than the off angle in the c axis direction, the crystal quality and flatness of the nitride semiconductor layers 110 to 150 formed on the growth surface 10a can be improved. Therefore, when the nitride semiconductor light emitting device 800 is manufactured, the light emission efficiency thereof can be improved.

Other structures and effects of the fifth embodiment are similar to those of the first and second embodiments.

### Sixth Embodiment

FIG. 12 is a sectional view illustrating the nitride semiconductor light emitting device according to a sixth embodiment of the present invention. Next, the nitride semiconductor light emitting device 900 (900A) according to the sixth embodiment of the present invention is described with reference to FIG. 12. At this point, in FIG. 12, the same reference symbols are used to designate corresponding structural elements and redundant description thereof is omitted as appropriate.

In the sixth embodiment, an AlN layer 910 is formed on the growth surface 10a of the nitride semiconductor substrate 10 so as to be in contact with the growth surface 10a in the structure of the fifth embodiment. More specifically, in the sixth embodiment, the AlN layer 910 is formed between the nitride semiconductor substrate 10 and the device structure (nitride semiconductor layer 200) in the structure of the fifth embodiment.

By forming the AlN layer 910 on the growth surface 10a of the nitride semiconductor substrate 10 in this way, the crystallinity is much improved compared with an AlN layer formed on other planes (for example, the c-plane). Further, the flatness is much improved compared with an AlN layer formed on a plane having an off angle which is other than the one defined above with respect to the m-plane (for example, a plane which does not have an off angle in the a axis direction, and a plane having the off angle in the c axis direction that is larger than the off angle in the a axis direction). Therefore, by forming the device structure (layered structure 200 (nitride semiconductor layers 110 to 150)) on the AlN layer 910, the crystal quality and flatness of the device structure (layered structure 200 (nitride semiconductor layers 110 to 150)) can be further improved.

Therefore, with this structure, the nitride semiconductor light emitting device 900 (900A) having a further improved light emission efficiency can be obtained.

At this point, the AlN layer 910 is inferior in conductivity to an AlGaN layer, an AlInGaN layer, a GaN layer or the like, and hence, it is better that, as illustrated in FIG. 12, the nitride semiconductor light emitting device have a lateral structure. Further, by peeling (removing) the AlN layer 910 together with the substrate, a vertical structure nitride semiconductor light emitting device can also be realized. In that case, the n-side nitride semiconductor layer 210 which forms the device structure is an example of the “semiconductor layer having a growth surface” according to the present invention.

Other structures and effects of the sixth embodiment are similar to those of the fifth embodiment.

### Modified Example of Sixth Embodiment

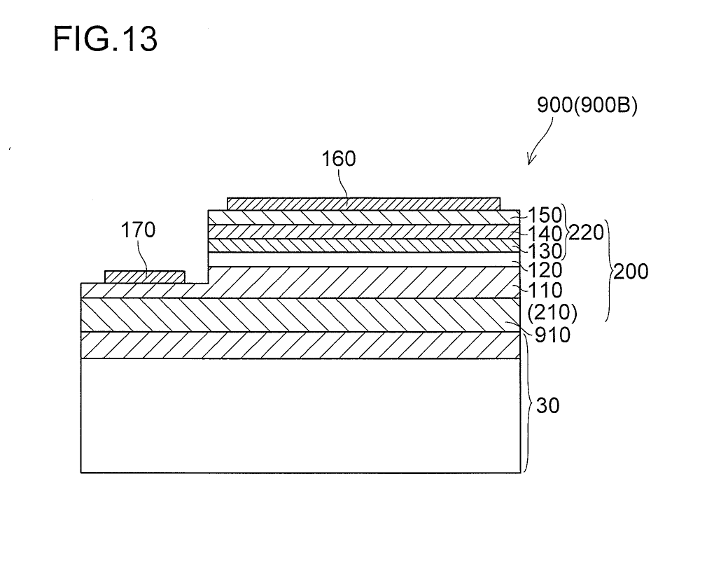

FIG. 13 is a sectional view illustrating the nitride semiconductor light emitting device according to a modified example of the sixth embodiment. Referring to FIG. 13, in the nitride semiconductor light emitting device 900 (900B) according to the modified example of the sixth embodiment, the AlN layer 910 is formed on the growth surface of the template substrate 30 described in the first to fourth embodiments. More specifically, while, in the sixth embodiment, a structure in which the AlN layer 910 is directly formed on the growth surface 10a of the nitride semiconductor substrate 10 is described, in this modified example of the sixth embodiment, the AlN layer 910 is directly formed on the growth surface of the template substrate 30.

Other structures of the modified example of the sixth embodiment are similar to those of the sixth embodiment.

### Example 1

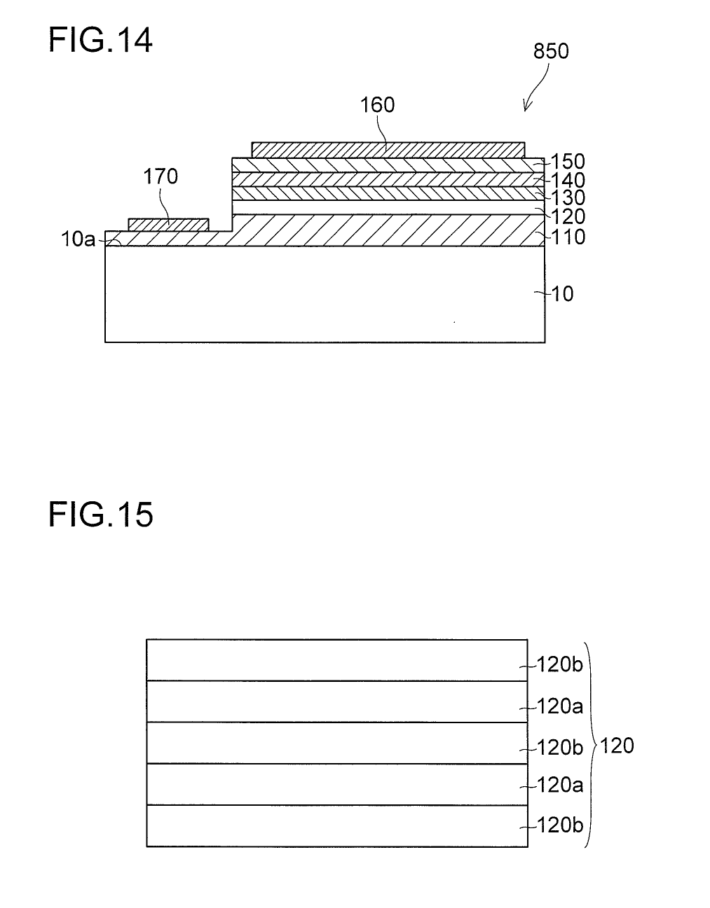

FIG. 14 is a sectional view illustrating the nitride semiconductor light emitting device according to Example 1. FIG. 15 is a sectional view illustrating a structure of an active layer of the nitride semiconductor light emitting device according to Example 1. A nitride semiconductor light emitting device 850 according to Example 1 is described with reference to FIGS. 14 and 15.

In Example 1, as illustrated in FIG. 14, an n-type Al_{0.45}Ga_{0.55}N layer 110 having a thickness of about 0.1 μm was formed on the growth surface 10a of the nitride semiconductor substrate 10. Further, the active layer 120 was formed on the n-type Al_{0.45}Ga_{0.55}N layer 110. The carrier blocking layer 130 having a thickness of about 15 nm formed of p-type Al_{0.75}Ga_{0.25}N, a p-type Al_{0.60}Ga_{0.40}N layer 140 having a thickness of about 20 nm, and a p-type GaN layer 150 having a thickness of about 50 nm were formed in this order on the active layer 120.

Further, as illustrated in FIG. 15, the active layer 120 was formed so as to have a quantum well structure by alternately laminating the barrier layers 120b and the quantum well layers 120a. The number of the quantum well layers 120a was two. At this point, in Example 2, the quantum well layers 120a were formed of Al_{0.36}Ga_{0.64}N while the barrier layers 120b were formed of Al_{0.45}Ga_{0.55}N. Further, in Example 1, the nitride semiconductor substrate 10 was a GaN substrate.

Further, in Example 1, by forming two electrodes (the p-side electrode 160 and the n-side electrode 170) on the top surface -side of the nitride semiconductor substrate 10, the nitride semiconductor light emitting device 850 was caused to have a lateral structure. The p-side electrode 160 and the n-side electrode 170 were similar to those in the above mentioned embodiments. At this point, in Example 1, by forming electrodes on the top surface -side and a bottom surface -side of the nitride semiconductor substrate 10, the nitride semiconductor light emitting device 850 can be formed so as to have a vertical structure.

Then, a GaN substrate having the off angle in the a axis direction that was equal to or smaller than one degree (substrate 1) and a GaN substrate having the off angle in the a axis direction that was larger than one degree (substrate 2) were used to manufacture nitride semiconductor light emitting devices, respectively, which were similar to the one as in Example 1 described above. With regard to the substrate 1, specifically, the off angle in the a axis direction was 0.8 degrees while the off angle in the c axis direction was −0.5 degrees. With regard to the substrate 2, specifically, the off angle in the a axis direction was 1.85 degrees while the off angle in the c axis direction was −0.2 degrees. Those devices were used to make a comparison of operating voltage and of intensity of emission due to current injection.

As a result, in the device using the GaN substrate having the off angle in the a axis direction that was larger than one degree (substrate 2), the operating voltage was lowered by about 0.8 V compared with that in the device using the GaN substrate having the off angle in the a axis direction that was equal to or smaller than one degree (substrate 1). With regard to the intensity of emission due to current injection, the emission intensity of the device using the substrate 2 was able to obtain light emission which was about three times as intense as that of the device using the substrate 1. This is supposed to be because, by setting the off angle in the a axis direction to be larger than one degree, the flatness was improved. By improving the flatness, the effect of suppressing light emission in a wavelength other than the predetermined light emission wavelength which occurred due to layer thickness fluctuations, the effect of causing the current injection to be uniform, and the like were supposed to be produced to increase the emission intensity.

### Example 2

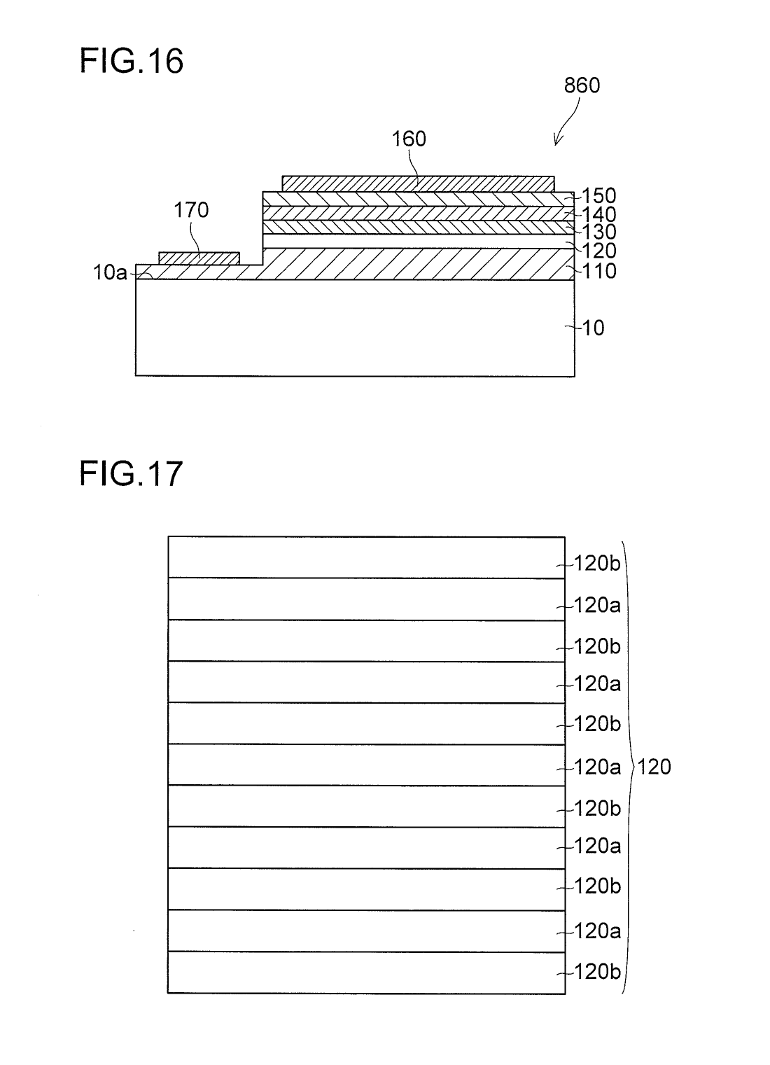

FIG. 16 is a sectional view illustrating the nitride semiconductor light emitting device according to Example 2. FIG. 17 is a sectional view illustrating a structure of an active layer of the nitride semiconductor light emitting device according to Example 2. A nitride semiconductor light emitting device 860 according to Example 2 is described with reference to FIGS. 16 and 17.

In Example 2, as illustrated in FIG. 16, an n-type Al_{0.50}Ga_{0.50}N layer 110 having a thickness of about 0.1 μm was formed on the growth surface 10a of the nitride semiconductor substrate 10. Further, the active layer 120, the carrier blocking layer 130 having a thickness of about 15 nm formed of p-type Al_{0.80}Ga_{0.20}N, a p-type Al_{0.50}Ga_{0.50}N layer 140 having a thickness of about 10 nm, and a p-type contact layer 150 having a thickness of about 50 nm formed of p-type Al_{0.10}Ga_{0.90}N were formed in this order on the n-type Al_{0.50}Ga_{0.50}N layer 110.

Further, as illustrated in FIG. 17, the active layer 120 was formed so as to have a quantum well structure by alternately laminating the barrier layers 120b and the quantum well layers 120a. The number of the quantum well layers 120a was five. At this point, in Example 2, the quantum well layers 120a were formed of Al_{0.4}Ga_{0.6}N while the barrier layers 120b were formed of Al_{0.50}Ga_{0.50}N. Further, in Example 2, the nitride semiconductor substrate 10 was a GaN substrate.

Further, in Example 2, similarly to Example 1, by forming two electrodes (the p-side electrode 160 and the n-side electrode 170) on the top surface -side of the nitride semiconductor substrate 10, the nitride semiconductor light emitting device 860 was caused to have a lateral structure. The p-side electrode 160 and the n-side electrode 170 were similar to those in the above mentioned embodiments. At this point, even in Example 2, by forming the electrodes on the top surface -side and the bottom surface -side of the nitride semiconductor substrate 10, the nitride semiconductor light emitting device 860 can be formed so as to have a vertical structure.

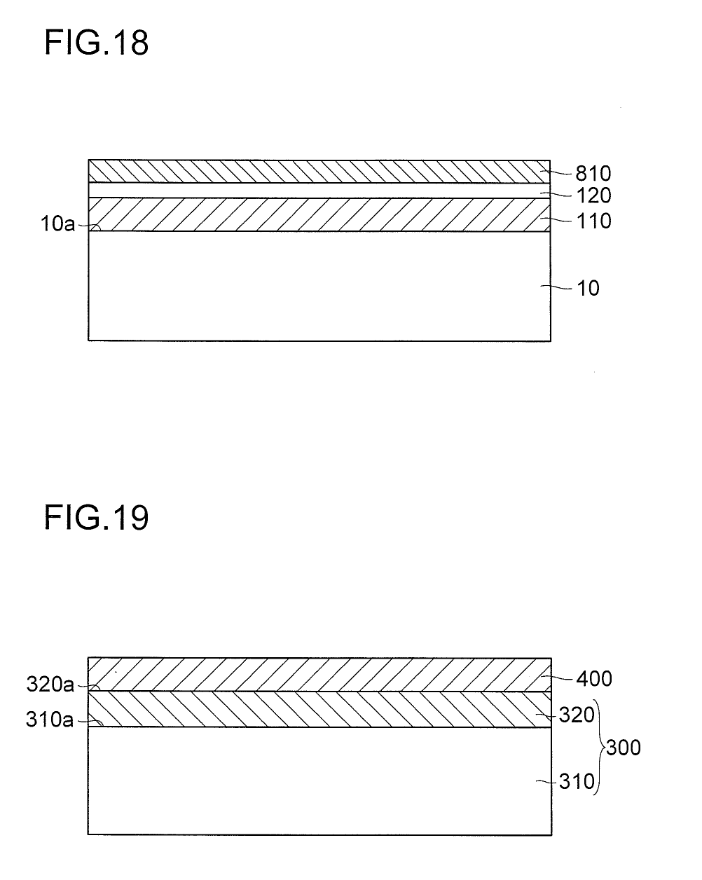

FIG. 18 is a sectional view of an evaluation structure which was used to confirm an effect of improving the light emission efficiency of the nitride semiconductor light emitting device according to Example 2.

As illustrated in FIG. 18, the evaluation structure (Example 2) is the same as the structure of Example 2 illustrated in FIG. 16 up to the nitride semiconductor substrate 10, the n-type Al_{0.50}Ga_{0.50}N layer 110, and the active layer 120, but is different from the structure of Example 2 in the semiconductor layer formed on the active layer 120. More specifically, in this evaluation structure, instead of the carrier blocking layer 130, the p-type Al_{0.50}Ga_{0.50}N layer 140, and the p-type contact layer 150, an AlN cap layer 810 having a thickness of about 20 nm was formed on the active layer 120. At this point, with regard to the nitride semiconductor substrate (GaN substrate) 10, the off angle in the a axis direction was 2.05 degrees while the off angle in the c axis direction was −0.15 degrees. Further, in this evaluation structure, an n-side electrode and a p-side electrode were not formed and there was only a semiconductor layered structure. The evaluation structure was used to make a measurement of PL (photoluminescence) intensity.

At this point, as evaluation structures for comparison, there were manufactured a sample in which a similar layered structure was formed on a GaN substrate having the c-plane as the growth surface (Comparative Example 1) and a sample in which a similar layered structure was formed on a GaN substrate that has, as the growth surface, a plane having the off angle in the c axis direction larger than the off angle in the a axis direction (Comparative Example 2). With regard to Comparative Example 2, specifically, the off angle in the a axis direction was 0.08 degrees while the off angle in the c axis direction was −1.2 degrees. With regard to those samples (Comparative Example 1 and Comparative Example 2), measurement of the PL intensity was made similarly to make a comparison with Example 2.

As a result, it was confirmed that the PL intensities of the evaluation structures using GaN substrates having planes that had off angles with respect to the m-plane as the growth surfaces (Example 2 and Comparative Example 2) were three times or more as intense as that of the evaluation structure in which the similar layered structure was formed on a GaN substrate that had the c-plane as the growth surface (Comparative Example 1). This is supposed to be because migration of group III atoms was extended to improve the crystal quality. Another reason is supposed to be the effect of suppressing the influence of spontaneous polarization.

Comparison between the evaluation structures using GaN substrates having as the growth surfaces planes having off angles with respect to the m-plane (Example 2 and Comparative Example 2) resulted in confirmation that the PL intensity of the evaluation structure of Example 2 was about twice as intense as that of the evaluation structure of Comparative Example 2. This is supposed to be because, in the evaluation structure of Example 2, by improving the flatness, light emission in a wavelength other than the predetermined light emission wavelength which occurred due to layer thickness fluctuations was suppressed to increase the emission intensity.

Further, from the above mentioned result, it was confirmed that, by setting the off angle in the a axis direction to be larger than the off angle in the c axis direction, the effect of improving the crystal quality and flatness was enhanced.

### Seventh Embodiment

FIG. 19 is a sectional view illustrating a semiconductor substrate according to a seventh embodiment of the present invention. Next, the semiconductor substrate used in the nitride semiconductor light emitting device according to the seventh embodiment is described with reference to FIG. 19.

As illustrated in FIG. 19, a semiconductor substrate 300 according to the seventh embodiment includes a base substrate 310 and the nitride semiconductor layer 320 formed on a growth surface 310a of the base substrate 310. The nitride semiconductor layer 320 forming the semiconductor substrate 300 has a growth surface 320a which is a plane having an off angle in the a axis direction and having an off angle in the c axis direction with respect to the m-plane. In the growth surface 320a, the off angle in the a axis direction is larger than the off angle in the c axis direction. Further, the off angle in the a axis direction is set to be larger than 0.1 degrees and equal to or smaller than 10 degrees. At this point, the off angle in the a axis direction is more preferably larger than one degree and equal to or smaller than 10 degrees. Further, the nitride semiconductor layer 320 is an example of the “semiconductor layer having a growth surface” according to the present invention.

Further, on the growth surface 320a of the semiconductor substrate 300 (nitride semiconductor layer 320), for example, the nitride semiconductor layer 400 containing Al is formed. More specifically, in the seventh embodiment, the nitride semiconductor layer 400 having a thickness of about 1.0 μm formed of AlₓIn_{y}Ga_{1-x-y}N is formed on the growth surface 320a of the nitride semiconductor layer 320.

At this point, as the base substrate 310, for example, a GaN substrate, an AlGaN substrate, an AlInGaN substrate, an AlN substrate, a sapphire substrate, a SiC substrate or a Si substrate can be used. Further, as the nitride semiconductor layer 320, for example, a GaN layer, an AlGaN layer, an AlInGaN layer, or an AlN layer can be used.

Further, as described above, when the nitride semiconductor layer 400 containing Al is formed on the nitride semiconductor layer 320 having the growth surface 320a, and when the growth surface has an off angle at least in the a axis direction with respect to the m-plane, with the off angle in the a axis direction being larger than an off angle in the c axis direction, as the Al composition ratio in the nitride semiconductor layer 400 becomes larger, the effect of improving the crystal quality when compared with other planes than the above mentioned plane (for example, the c-plane) becomes greater. Further, the effect of improving the flatness with respect to a plane having an off angle which is other than the one defined above with respect to the m-plane (for example, a plane which does not have an off angle in the a axis direction, and a plane having the off angle in the c axis direction that is larger than the off angle in the a axis direction) becomes greater. At this point, when a specific nitride semiconductor light emitting device is formed, an Al composition ratio x in the nitride semiconductor layer 400 formed on the growth surface 320a is preferably in a range of 0.15≦x≦1.00, and more preferably in a range of 0.30≦x≦1.00. Further, an In Composition ratio y is preferably in a range of 0.00≦y≦0.12.

By setting the Al composition ratio x to be equal to or larger than 15% (0.15), the influence of the off angle becomes greater, and thus, the effect of improving the surface with respect to a plane having an off angle which is other than the one defined above with respect to the m-plane (for example, a plane which does not have an off angle in the a axis direction, and a plane having the off angle in the c axis direction that is larger than the off angle in the a axis direction) becomes greater. Further, by setting the Al composition ratio x to be equal to or larger than 30% (0.30), not only the influence of the off angle but also the influence of migration becomes greater, and thus, the effect thereof becomes greater and the effect of improving the crystal quality when compared with other planes (for example, the c-plane) becomes further greater. In addition, the flatness with respect to a plane having an off angle which is other than the one defined above with respect to the m-plane (for example, a plane which does not have an off angle in the a axis direction, and a plane having the off angle in the c axis direction larger than the off angle in the a axis direction) is improved. By setting the Al composition ratio x to be equal to or larger than 50% (0.50), the effect of improvement when compared with other planes (for example, the c-plane) becomes greater, which is preferred.

By using the semiconductor substrate 300 structured in this way, the crystal quality and flatness of the nitride semiconductor layer containing Al which is formed on the growth surface 320a thereof can be improved. This can also be confirmed by the result of measurement of the PL (photoluminescence) intensity. More specifically, a sample in which the nitride semiconductor layer 400 was formed on the growth surface 320a of the nitride semiconductor layer 320 (for example, an AlGaN layer) according to the seventh embodiment and a sample in which a semiconductor layer similar to the nitride semiconductor layer 400 was formed on the nitride semiconductor layer (for example, an AlGaN layer) having the c-plane as the growth surface were manufactured to make a comparison of the PL intensity. The result obtained was that the light emission efficiency was improved with the sample using the nitride semiconductor layer 320 (semiconductor substrate 300) according to the seventh embodiment. This means that, by using the nitride semiconductor layer 320 (semiconductor substrate 300) according to the seventh embodiment, the light emission efficiency can be improved. This is supposed to be because the surface migration of group III atoms which reached the substrate surface (the growth surface 320a of the nitride semiconductor layer 320) was extended.

Further, according to the seventh embodiment, by using the semiconductor substrate 300 described above, when the nitride semiconductor layer 400 is formed on the growth surface 320a, even if the growth temperature is not set to be a high temperature at which the temperature load on a crystal growth system (MOCVD system) is heavy (for example, equal to or higher than 1,200° C.), the crystal quality can be improved. Therefore, by using the semiconductor substrate 300 described above, the temperature load on the crystal growth system (MOCVD system) can be reduced. In addition, even if the growth is caused to occur at a temperature lower than a conventionally used growth temperature (for example, about 1,000° C.), degradation in flatness can be suppressed.

Further, by causing the nitride semiconductor layer 400 formed on the growth surface 320a to be the nitride semiconductor layer containing In (for example, an AlInGaN layer), a layer which is excellent in flatness can be formed at a lower temperature. Therefore, taking into consideration the temperature load on the crystal growth system, it is preferable that the nitride semiconductor layer 400 formed on the growth surface 320a be the nitride semiconductor layer containing Al and In. Further, by forming the nitride semiconductor layer 400 of the nitride semiconductor layer containing Al and In (for example, an AlInGaN layer) in this way, parameters for controlling distortion when the device structure is formed on the growth surface 320a increase by one, and hence, the design flexibility can be enhanced. At this point, by setting an In composition ratio y to be equal to or smaller than 12% (0.12), a crystal which is excellent in flatness can be realized.

On the other hand, the nitride semiconductor layer 400 formed on the growth surface 320a can also be formed of the nitride semiconductor layer which does not contain In (for example, an AlGaN layer). With this structure, the effect of improving the crystal quality and the effect of improving the flatness can be further enhanced. More specifically, when the nitride semiconductor layer 400 having the growth surface 320a is used, by growing on the growth surface 320a the nitride semiconductor layer which does not contain In (for example, an AlGaN layer), more outstanding effect of improving the crystal quality and more outstanding effect of improving the flatness can be obtained.

Further, by setting the off angle in the a axis direction in the growth surface 320a to be larger than 0.1 degrees and equal to or smaller than 10 degrees, the pyramid-like protruding portions can be suppressed, and hence, the flatness can be improved. Further, satisfactory surface morphology can be obtained, and thus, variations in the layer thickness can be suppressed. This can suppress a generation of the crack, and can improve the light emission efficiency and reduce the device resistance. Further, by setting the off angle in the a axis direction to be larger than one degree and equal to or smaller than 10 degrees, the above mentioned effect obtained can be further greater.

At this point, the nitride semiconductor layer 400 formed on the growth surface 320a can also be an AlN layer.

As described above, in the semiconductor substrate 300 according to the seventh embodiment, the crystallinity and flatness of the nitride semiconductor layer 400 containing Al which is formed on the growth surface 320a thereof can be improved. Therefore, by using the semiconductor substrate 300 to form a specific device structure, the nitride semiconductor light emitting device having a high light emission efficiency can be formed.

Further, the semiconductor substrate 300 is very useful as a seed substrate for forming the nitride semiconductor substrate. For example, with the nitride semiconductor layer 320 of the semiconductor substrate 300 being as a seed layer, by forming the nitride semiconductor layer 400 containing Al having a thickness with which the nitride semiconductor layer 400 can stand on its own (for example, about 350 μm) on the growth surface 320a of the nitride semiconductor layer 320, the nitride semiconductor substrate such as an AlGaN substrate, an AlInGaN substrate, or an AlN substrate can be obtained. In this case, it is preferable that the nitride semiconductor layer 320 to be the seed layer and the nitride semiconductor layer 400 formed on the growth surface 320a thereof be of the same composition. Further, here, the semiconductor substrate 300 can be peeled using polishing, etching, laser lift-off, or the like, or, alternatively, can remain without being peeled. Further, only the base substrate 310 of the semiconductor substrate 300 can be peeled.

Further, the semiconductor substrate 300 with the nitride semiconductor layer 400 formed thereon can be used as the substrate. For example, an AlN layer can be formed on the growth surface 320a of the nitride semiconductor layer 320 in the semiconductor substrate 300 and a device structure can be formed on a principal plane of the AlN layer. The principal plane of the AlN layer formed on the growth surface 320a is, similarly to the growth surface 320a, a plane having an off angle in the a axis direction and having an off angle in the c axis direction with respect to the m-plane, the off angle in the a axis direction being larger than the off angle in the c axis direction. Therefore, with regard to the nitride semiconductor layer containing Al which is formed on the principal plane of the AlN layer, the crystal quality and flatness can also be improved. Therefore, when a light emitting device is formed using such a substrate, the light emission efficiency thereof can be improved and the operating voltage thereof can be lowered.

Further, the growth surface of the semiconductor substrate 300 can be formed only of the nitride semiconductor substrate (for example, a GaN substrate, an AlGaN substrate, an AlInGaN substrate, or an AlN substrate) that has a growth surface having a structure similar to that of the growth surface 320a of the nitride semiconductor layer 320.

At this point, when the base substrate 310 of the semiconductor substrate 300 is a GaN substrate, as opposed to a sapphire substrate or the like, a GaN substrate is conductive, and thus, the design flexibility of the device can be enhanced. Further, compared with a case where a heterosubstrate such as a sapphire substrate is used, the differences in thermal expansion coefficient and in lattice constant from AlInGaN are small, and thus, an AlInGaN layer having satisfactory crystallinity can be formed.

Further, when the base substrate 310 of the semiconductor substrate 300 is an AlGaN substrate, absorption of ultraviolet light can be suppressed. Further, when the base substrate 310 of the semiconductor substrate 300 is an AlInGaN substrate, the flexibility of the lattice constant is enhanced, and thus, the design flexibility of the layered structure forming the device can be enhanced. Further, when the base substrate 310 of the semiconductor substrate 300 is an AlN substrate, in addition to an effect similar to that of an AlGaN substrate, an effect of improving heat dissipation can be produced.

Further, as the base substrate 310 of the semiconductor substrate 300, the substrate other than the nitride semiconductor substrate such as a sapphire substrate, a SiC substrate, or a Si substrate can also be used. Even in this case, by forming the growth surface 320a of the nitride semiconductor layer 320 formed on the base substrate 310 as described above, the effect of improving the crystal quality and the effect of improving the flatness can be obtained. In this case, as described in the fourth embodiment, a plurality of nitride semiconductor layers can be laminated on the base substrate 310.

### Example 3

In Example 3, a GaN substrate was used as an example of the semiconductor substrate, and an AlGaN layer having a thickness of about 0.1 μm was formed on the growth surface thereof. With regard to the growth surface, the off angle in the a axis direction was −1.99 degrees and the off angle in the c axis direction was −0.20 degrees. Further, samples in which the Al composition ratios of the AlGaN layer were 5%, 10%, 18%, and 35%, respectively, were manufactured and measurement of the PL intensity was made.

At this point, as Comparative Sample 1, a sample in which a similar AlGaN layer was formed on a GaN substrate having the c-plane as the growth surface was manufactured. Further, as Comparative Sample 2, a sample in which a similar AlGaN layer was formed on a GaN substrate that has, as the growth surface, a plane having the off angle in the c axis direction larger than the off angle in the a axis direction was manufactured. With regard to the specific off angles, the off angle in the a axis direction was −0.07 degrees while the off angle in the c axis direction was −0.35 degrees. With regard to those samples, measurement of the PL intensity was made similarly to make a comparison with Example 3.

When the Al composition ratio in the AlGaN layer was 5% to 10%, the exhibited PL intensity of the samples using GaN substrates that has, as the growth surfaces, planes having off angles with respect to the m-plane (Example 3 and Comparative Sample 2) was substantially equal to that of the sample using a GaN substrate having the c-plane as the growth surface (Comparative Sample 1). However, when the Al composition ratio was 18% to 35%, the PL intensity was higher than that of Comparative Sample 1. Further, the rate of increase in the PL intensity with respect to Comparative Sample 1 obtained when the Al composition ratio was 35% was about twice as high as that obtained when the Al composition ratio was 18%. This is supposed to be because, as the Al composition ratio becomes larger, the influence of migration of Al becomes greater, and the effect of extending migration is enhanced more in a GaN substrate that has, as the growth surface, a plane having an off angle with respect to the m-plane.

Comparison between the samples using GaN substrates that has, as the growth surfaces, planes having off angles with respect to the m-plane (Example 3 and Comparative Sample 2) made it clear that, when the Al composition ratio in the AlGaN layer was 5% to 10%, substantially the same PL intensity was obtained, but, when the Al composition ratio was 18% to 35%, the PL intensity of Example 3 was about 1.5 times as intense as that of Comparative Sample 2. Further, in Example 3, the flatness of the layer surface was more satisfactory than that in Comparative Sample 2. The influence was outstanding when the Al composition ratio was higher, i.e., 18% and 35%. It is supposed that, by this improvement in the flatness, light emission in a wavelength other than the predetermined light emission wavelength which occurred due to layer thickness fluctuations was suppressed to increase the emission intensity.

Further, from the above mentioned result, it was confirmed that, by setting the off angle in the a axis direction to be larger than the off angle in the c axis direction, the effect of improving the crystal quality and flatness was enhanced.

At this point, the embodiments disclosed herein are only exemplary in all respects and should not be regarded as limitation on the present invention. The scope of the present invention is defined not by the above description of the embodiments but by the scope of the claims, and includes all equivalent variations and modifications which fall within the scope of the claims.

For example, in the above mentioned first to seventh embodiments, MOCVD is used to cause crystal growth of the nitride semiconductor layers to occur on the substrate, but the present invention is not limited thereto, and a crystal growth method other than MOCVD can be used to cause crystal growth of the nitride semiconductor layers to occur on the substrate. For example, molecular beam epitaxy (MEB), hydride vapor phase epitaxy (HDVPE), or the like can be used to cause crystal growth of the nitride semiconductor layers to occur.

Further, in the above mentioned first to seventh embodiments, the growth surface of the nitride semiconductor layer (nitride semiconductor substrate) is a plane having an off angle in the a axis direction and having an off angle in the c axis direction with respect to the m-plane, but the present invention is not limited thereto. It is only necessary that the growth surface of the nitride semiconductor layer (nitride semiconductor substrate) be a plane having an off angle at least in the a axis direction with respect to the m-plane. More specifically, the off angle in the c axis direction can be 0 degrees.

Further, in the above mentioned first to sixth embodiments, the cases where the present invention is applied to a light emitting diode device as an example of the nitride semiconductor device are described, but the present invention is not limited thereto, and the present invention can be applied to the nitride semiconductor light emitting device other than a light emitting diode device. For example, the present invention can be applied to the nitride semiconductor laser device as an example of the nitride semiconductor light emitting device. At this point, when a GaN substrate is used as the substrate, a GaN substrate absorbs ultraviolet light, and thus, in order to reduce leakage of light to the substrate, it is preferable that a multilayer film reflector or the like be formed between the substrate and the active layer. Further, when the present invention is applied to a light emitting diode device, in extracting light on the substrate -side, it is preferred to peel the GaN substrate or to remove by etching or the like a light extraction part in the GaN substrate. This can make it easier to extract light on the substrate -side. Further, when light is extracted from a -side opposite to the substrate with respect to the active layer, if a GaN layer (p-type GaN layer) is formed as a contact layer, light is absorbed in the GaN layer, and thus, it is preferable that the light extraction part in the p-type GaN layer be removed by etching or the like.

Further, the present invention is not limited to nitride semiconductor light emitting devices such as a light emitting diode device or a semiconductor laser device, and can be applied to devices as a whole using the nitride semiconductor such as electronic devices (for example, a power transistor, an integrated circuit (IC), or a large scale integration (LSI)).

At this point, in the above mentioned embodiments, the nitride semiconductor layer having the growth surface is formed by being grown on the substrate. The phrase “being grown on the substrate” as used herein includes a case of being grown directly on a growth surface of the substrate and a case where the nitride semiconductor having a growth surface is formed on the substrate and the nitride semiconductor layer is formed thereon. Further, the growth surface of the nitride semiconductor layer is not limited to the principal plane, and a planet formed in lateral growth or the like using a mask or the like can also be the growth surface. More specifically, the above mentioned phrase “being grown on the substrate” includes a case where the nitride semiconductor layer is grown on such a growth surface.

Further, in the above mentioned embodiments, the thickness, composition, and the like of the device structure (nitride semiconductor layers) formed on the growth surface of the nitride semiconductor layer can be appropriately combined or changed to match desired characteristics. For example, a semiconductor layer can be added or deleted, and the order of the semiconductor layers can be partly changed. Further, for example, a semiconductor layer having a superlattice structure can be formed between the nitride semiconductor layer 20 and the n-type nitride semiconductor layer 110 (for example, an n-type AlInGaN layer or an n-type AlGaN layer) in FIG. 3. In this case, by forming the superlattice structure on the growth surface of the nitride semiconductor layer, a superlattice structure which is excellent in flatness can be formed, which is preferred. Further, the conductivity type can be changed with regard to a part of the semiconductor layers. More specifically, the conductivity type can be freely changed insofar as basic characteristics of the nitride semiconductor device (including the nitride semiconductor laser device and a light emitting diode device) are obtained.

Further, when the difference between the lattice constant of the nitride semiconductor layer laminated on the substrate and the lattice constant of the substrate is large, the crack can develop in the laminated nitride semiconductor layer. In this case, by forming a groove (recess) in the substrate, such a generation of the crack can be suppressed.

Further, in the above mentioned first to sixth embodiments, as an example of the light emitting diode device, a light emitting diode device which emits light in the ultraviolet wavelength range (deep ultraviolet wavelength range) is described, but the present invention is not limited thereto, and the light emitting device can emit light in a wavelength range other than the ultraviolet (deep ultraviolet) wavelength range.

Further, in the above mentioned first embodiment, an example in which the nitride semiconductor light emitting device is mounted on a can type package is described, but the present invention is not limited thereto and the nitride semiconductor light emitting device can be mounted on a package other than the package described in the first embodiment. Further, with regard to the nitride semiconductor light emitting device described in the second to sixth embodiments, similarly to the case of the first embodiment, by being mounted on a package, the semiconductor optical device can be formed.

Further, in the above mentioned embodiments, a template substrate in which one or two nitride semiconductor layers are formed on the substrate is described, but the present invention is not limited thereto, and the template substrate can be formed by forming three or more nitride semiconductor layers on the substrate. Here, the nitride semiconductor layers formed on the substrate can be of different composition or can be of the same composition.

At this point, embodiments obtained by appropriately combining the technologies (structures) disclosed above are also within the technical scope of the present invention.

What is claimed is:

1. A nitride semiconductor device, comprising:
a semiconductor layer comprising the nitride semiconductor, the semiconductor layer having a growth surface; and
the nitride semiconductor layer formed on the growth surface of the semiconductor layer, the nitride semiconductor layer including an active layer which has a quantum well structure, wherein
the active layer includes a quantum well layer comprising the nitride semiconductor containing Al, and
the growth surface of the semiconductor layer comprises a plane having an off angle at least in an a axis direction with respect to an m-plane, and the off angle in the a axis direction being larger than an off angle in a c axis direction.

2. The nitride semiconductor device according to claim 1, wherein
both of the off angle in the a axis direction and the off angle in the c axis direction are larger than 0.1 degrees.

3. The nitride semiconductor device according to claim 1, wherein
the off angle in the a axis direction is larger than 0.1 degree and equal to or smaller than 10 degrees.

4. The nitride semiconductor device according to claim 1, wherein
the off angle in the a axis direction is larger than one degree and equal to or smaller than 10 degrees.

5. The nitride semiconductor device according to claim 1, wherein
the quantum well layer comprises a semiconductor represented by a composition formula below.
Alₓ₁In_{y1}Ga_{1-x1-y1}N
where 0<x1≦1 and 0≦y1≦1

6. The nitride semiconductor device according to claim 5, wherein
the Al composition ratio x1 in the quantum well layer is in a range of 0.15≦x1≦0.90.

7. The nitride semiconductor device according to claim 5, wherein
the In composition ratio y1 in the quantum well layer is in a range of 0.00≦y1≦0.12.

8. The nitride semiconductor device according to claim 1, wherein
the semiconductor layer comprises the nitride semiconductor containing Al, and
an Al composition ratio in the semiconductor layer is larger than an Al composition ratio in the quantum well layer and is equal to or larger than 0.20 and equal to or smaller than 1.00.

9. The nitride semiconductor device according to claim 1, wherein
the active layer includes a barrier layer which comprises a semiconductor represented by a composition formula below, and
an Al composition ratio x2 in the barrier layer is larger than an Al composition ratio in the quantum well layer.
Alₓ₂In_{y2}Ga_{1-x2-y2}N
where 0<x2<1 and 0≦y2≦1

10. The nitride semiconductor device according to claim 9, wherein the Al composition ratio x2 in the barrier layer is in a range of 0.20≦x2≦1.00.

11. The nitride semiconductor device according to claim 9, wherein
when the quantum well layer comprises a semiconductor represented by a composition formula below,
the In composition ratio y2 in the barrier layer is smaller than the In composition ratio y1 in the quantum well layer and is in a range of 0.00≦y2≦0.08.
Alₓ₁In_{y1}Ga_{1-x1-y1}N
where 0<x1≦1 and 0≦y1≦1

12. The nitride semiconductor device according to claim 9, wherein
the barrier layer comprises AlGaN or AlInGaN.

13. The nitride semiconductor device according to claim 1, wherein
the quantum well layer comprises AlGaN or AlInGaN.

14. The nitride semiconductor device according to claim 1, further comprising an AlN layer formed on the growth surface of the semiconductor layer so as to be in contact with the growth surface.

15. The nitride semiconductor device according to claim 1, wherein
the nitride semiconductor layer formed on the growth surface of the semiconductor layer further comprises an n-side nitride semiconductor layer formed on the semiconductor layer side with respect to the active layer, and a p-side nitride semiconductor layer formed on a side opposite to the n-side nitride semiconductor layer with respect to the active layer, and
the n-side nitride semiconductor layer does not comprise a GaN layer.

16. The nitride semiconductor device according to claim 1, wherein
a wavelength of light emitted from the active layer is equal to or larger than 240 nm and equal to or smaller than 360 nm.

17. The nitride semiconductor device according to claim 1, wherein
a wavelength of light emitted from the active layer is equal to or larger than 260 nm and equal to or smaller than 300 nm.

18. The nitride semiconductor device according to claim 1, wherein
the semiconductor layer having the growth surface comprises at least one of AlGaN, AlInGaN, or AlN.

19. The nitride semiconductor device according to claim 1, further comprising a substrate which forms the semiconductor layer having the growth surface, wherein
the substrate comprises at least one of an AlGaN substrate, an AlInGaN substrate, or an AlN substrate.

20. The nitride semiconductor device according to claim 1, further comprising a substrate which forms the semiconductor layer having the growth surface, wherein
the substrate comprises a GaN substrate.

21. The nitride semiconductor device according to claim 1, further comprising a template substrate in which the semiconductor layer is formed on a base substrate, wherein
the nitride semiconductor layer including the active layer is formed on the template substrate.

22. A semiconductor optical device, comprising the nitride semiconductor device according to claim 1.
